(19) United States
(12) Patent Application Publication
(10) Pub. No.: US 2023/0305050 A1
(43) Pub. Date: Sep. 28, 2023

(54) STATE ESTIMATION METHOD FOR MULTI-STAGE VOLTAGE SAG

(71) Applicant: SICHUAN UNIVERSITY, Chengdu (CN)

(72) Inventors: Ying WANG, Chengdu (CN); Haishan HE, Chengdu (CN); Xianyong XIAO, Chengdu (CN); Wengxi HU, Chengdu (CN); Yunzhu CHEN, Chengdu (CN)

(73) Assignee: SICHUAN UNIVERSITY, Chengdu (CN)

(21) Appl. No.: 18/082,611

(22) Filed: Dec. 16, 2022

(30) Foreign Application Priority Data
Mar. 3, 2022 (CN) 202210201077.X

(51) Int. Cl. G01R 31/08

(52) U.S. Cl. CPC G01R 31/088; G01R 31/086

(57) ABSTRACT

A state estimation method for a multi-stage voltage sag comprises analyzing characteristics of multi-stage voltage sags due to different causes. A method for determining the cause of sudden change time of an amplitude of the multi-stage voltage sag is based on a jump characteristic of the sag amplitude. Calculation methods of a relay protection action matrix and a faulty line set are utilized to preliminarily obtain a faulty line set based on the fault clearing time of a relay protection device and other characteristics to effectively reduce a calculation amount of sag state estimation. Based on a substantive characteristic that different events cause a change of system impedance, a method for inferring a cause of an event in each stage of the multi-stage voltage sag is used to improve the accuracy of the state estimation. The state estimation method reduces the difficulty in applying to the multi-stage voltage sag.

### CROSS REFERENCE TO THE RELATED APPLICATION

This application claims priority of Chinese application No. 202210201077.X, filed on Mar. 03, 2022, the entire content of which is incorporated herein by reference.

### TECHNICAL FIELD

The present disclosure relates to the technical field of voltage sag state estimation, specifically, to a state estimation method for a multi-stage voltage sag.

### BACKGROUND

Existing voltage sag state estimation methods are mainly used for a single-stage rectangular sag caused by a short circuit, and there is no state estimation method suitable for a multi-stage voltage sag. Unfortunately, existing researches show that the multi-stage voltage sag occurs more often, and the multi-stage voltage sag cannot be ignored. For example, with the development of a new power system, the proportion of distributed generation (DG) devices connected to the system is getting higher. During the short circuit fault, a sag may cause a trip of a single DG device or cascading trips of a plurality of DG devices, thus forming a complex multi-stage voltage sag. In addition, staged protection commonly used in the power system, such as distance protection, may also cause the multi-stage voltage sag due to its action characteristics.

In voltage sag state estimation, a sag amplitude of an unmonitored bus needs to be estimated by using a short-circuit calculation formula. A short-circuit calculation method is a well-known method. Short-circuit calculation methods corresponding to different fault types are as follows.

It is assumed that ^{m} is a to-be-solved bus, a line ^{l}ᵢⱼ between buses i and j is faulty, f is a fault point, P is a normalized distance from the point f to the bus i . A value range of p is [0, 1], representing f from i to the j according to the following expression:

$$p = \frac{{L}_{i f}}{{L}_{i f}} , p ∈ \left[0 , 1\right] \qquad \text{(1)}$$

Where L_{if} represents the distance from the bus i to the fault point f, and Lᵢⱼ represents the length of the line lᵢⱼ .

### Three-Phase Short Circuit Fault

A three-phase voltage amplitude caused by a three-phase fault of the bus m is as follows:

$$f \left({Z}_{m f}^{1} , {Z}_{f f}^{1}\right) = {V}_{m}^{\text{pref}} - \frac{{Z}_{m f}^{1}}{{Z}_{f f}^{1} + {R}_{f}} {V}_{f}^{\text{pref}} \qquad \text{(2)}$$

In the above formula, R_{f} represents fault resistance, and

$${V}_{m}^{\text{pref}}$$

and

$${V}_{f}^{\text{pref}}$$

respectively represent voltages of the bus ^{m} and the fault point f before the fault. The voltage of the bus before a sag can be obtained through power flow calculation by using a power system simulation tool, and the voltage of the fault point before the sag can be expressed as follows:

$${V}_{f}^{\text{pref}} = \left(1 - k\right) {V}_{i}^{\text{pref}} + k {V}_{j}^{\text{pref}} \qquad \text{(3)}$$

### Single-Phase-to-Ground Fault

It is assumed that the single-phase-to-ground fault occurs in phase A. A voltage amplitude of each phase of the bus ^{m} is as follows:

$$\left\{\begin{matrix}{V}_{m , A} = {V}_{m , A}^{\text{pref}} - \frac{{Z}_{m f}^{0} + {Z}_{m f}^{1} + {Z}_{m f}^{2}}{{Z}_{f f}^{0} + {Z}_{f f}^{1} + {Z}_{f f}^{2} + 3 {R}_{f}} {V}_{f , A}^{\text{pref}} \\ {V}_{m , B} = {α}^{2} {V}_{m , A}^{\text{pref}} - \frac{{Z}_{m f}^{0} + {α}^{2} {Z}_{m f}^{1} + α {Z}_{m f}^{2}}{{Z}_{f f}^{0} + {Z}_{f f}^{1} + {Z}_{f f}^{2} + 3 {R}_{f}} {V}_{f , A}^{\text{pref}} \\ {V}_{m , C} = α {V}_{m , A}^{\text{pref}} - \frac{{Z}_{m f}^{0} + α {Z}_{m f}^{1} + {α}^{2} {Z}_{m f}^{2}}{{Z}_{f f}^{0} + {Z}_{f f}^{1} + {Z}_{f f}^{2} + 3 {R}_{f}} {V}_{f , A}^{\text{pref}}\end{matrix}\right) \qquad \text{(4)}$$

In the above formulas, α = e^{j120°} represents a rotation factor.

### (3) Two-Phase Fault

It is assumed that the two-phase fault occurs in phases B and C. The voltage amplitude of each phase of the bus ^{m} is as follows:

$$\left\{\begin{matrix}{V}_{m , A} = {V}_{m , A}^{\text{pref}} - \frac{{Z}_{m f}^{0} + {Z}_{m f}^{1} + {Z}_{m f}^{2}}{{Z}_{f f}^{0} + {Z}_{f f}^{1} + {Z}_{f f}^{2} + 3 {R}_{f}} {V}_{f , A}^{\text{pref}} \\ {V}_{m , B} = {α}^{2} {V}_{m , A}^{\text{pref}} - \frac{{Z}_{m f}^{0} + {α}^{2} {Z}_{m f}^{1} + α {Z}_{m f}^{2}}{{Z}_{f f}^{0} + {Z}_{f f}^{1} + {Z}_{f f}^{2} + 3 {R}_{f}} {V}_{f , A}^{\text{pref}} \\ {V}_{m , C} = α {V}_{m , A}^{\text{pref}} - \frac{{Z}_{m f}^{0} + α {Z}_{m f}^{1} + {α}^{2} {Z}_{m f}^{2}}{{Z}_{f f}^{0} + {Z}_{f f}^{1} + {Z}_{f f}^{2} + 3 {R}_{f}} {V}_{f , A}^{\text{pref}}\end{matrix}\right) \qquad \text{(5)}$$

### Two-Phase-to-Ground Fault

It is assumed that the two-phase-to-ground fault occurs in phases B and C. The voltage amplitude of each phase of the bus ^{m} is as follows:

$$\left\{\begin{matrix}{V}_{m , A} = {V}_{m , A}^{\text{pref}} - \frac{{Z}_{m f}^{1} \left({Z}_{f f}^{0} + {Z}_{f f}^{2} + 2 {R}_{f}\right) - {Z}_{m f}^{2} \left({Z}_{f f}^{0} + {R}_{f}\right) - {Z}_{m f}^{0} \left({Z}_{f f}^{2} + {R}_{f}\right)}{\left({Z}_{f f}^{0} {Z}_{f f}^{1} + {Z}_{f f}^{1} {Z}_{f f}^{2} + {Z}_{f f}^{2} {Z}_{f f}^{0}\right) + 2 {R}_{f} \left({Z}_{f f}^{0} + {Z}_{f f}^{1} + {Z}_{f f}^{2}\right) + 3 {R}_{f}^{2}} {V}_{f , A}^{\text{pref}} \\ {V}_{m , B} = {α}^{2} {V}_{m , A}^{\text{pref}} - \frac{{α}^{2} {Z}_{m f}^{1} \left({Z}_{f f}^{0} + {Z}_{f f}^{2} + 2 {R}_{f}\right) - α {Z}_{m f}^{2} \left({Z}_{f f}^{0} + {R}_{f}\right) - {Z}_{m f}^{0} \left({Z}_{f f}^{2} + {R}_{f}\right)}{\left({Z}_{f f}^{0} {Z}_{f f}^{1} + {Z}_{f f}^{1} {Z}_{f f}^{2} + {Z}_{f f}^{2} {Z}_{f f}^{0}\right) + 2 {R}_{f} \left({Z}_{f f}^{0} + {Z}_{f f}^{1} + {Z}_{f f}^{2}\right) + 3 {R}_{f}^{2}} {V}_{f , A}^{\text{pref}} \\ {V}_{m , C} = α {V}_{m , A}^{\text{pref}} - \frac{α {Z}_{m f}^{1} \left({Z}_{f f}^{0} + {Z}_{f f}^{2} + 2 {R}_{f}\right) - {α}^{2} {Z}_{m f}^{2} \left({Z}_{f f}^{0} + {R}_{f}\right) - {Z}_{m f}^{0} \left({Z}_{f f}^{2} + {R}_{f}\right)}{\left({Z}_{f f}^{0} {Z}_{f f}^{1} + {Z}_{f f}^{1} {Z}_{f f}^{2} + {Z}_{f f}^{2} {Z}_{f f}^{0}\right) + 2 {R}_{f} \left({Z}_{f f}^{0} + {Z}_{f f}^{1} + {Z}_{f f}^{2}\right) + 3 {R}_{f}^{2}} {V}_{f , A}^{\text{pref}}\end{matrix}\right) \qquad \text{(6)}$$

The sag is a most serious disturbance to a sensitive device and cannot be avoided. Voltage sag levels at different positions in the system should be accurately reflected. Therefore, a monitoring device must be installed to monitor the voltage sag. The power grid is huge and complex. Therefore, the monitoring device can be installed only on some buses in the system due to the monitoring cost and information processing capability. How to use monitoring data from limited monitoring devices to estimate a sag level (mainly including the amplitude and duration of the voltage sag) of the unmonitored bus is an important research task, which is also referred to as the voltage sag state estimation. The existing voltage sag state estimation methods are mainly used for the single-stage sag caused by the short circuit fault and cannot be used for state estimation of the multi-stage voltage sag. As the multi-stage voltage sag occurs more often, it is important to propose a state estimation method suitable for the multi-stage voltage sag.

Difficulties of multi-stage state estimation are as follows. 1. The multi-stage voltage sag is mainly caused by the disconnection of the DG device from the power grid or trips of protection devices on two sides of a line at different times during the short circuit fault. Therefore, figuring out how to determine the causes of sags at different stages is the first challenge. 2. The position of the short circuit fault is an important factor affecting the voltage amplitude. Therefore, how to preliminarily obtain a possible faulty line set and reduce a calculation amount of MVSSE is the second challenge. 3. During the short circuit fault, the voltage amplitude at the same fault position is also affected by the quantity and sequence of DG devices disconnected from the power grid, the tripping condition of a protection device on a faulty line, and other events. Therefore, how to infer a specific cause of each stage of a sag event and improve the accuracy of the MVSSE is the third challenge.

### Explanation of Terms Used in the Present Disclosure

Voltage sag: The International Institute of Electrical and Electronics Engineers (IEEE) defines voltage sag as a power quality phenomenon in which an effective value of a supply voltage drops rapidly to a value within the range of 0.1 to 0.9 p.u. and the drop lasts 0.5 cycles to 1 min.

Voltage sag state estimation: It is a method for estimating a voltage sag state (including a sag frequency, a voltage sag amplitude, or a duration of an unmonitored bus in a certain period of time) of the unmonitored bus based on the monitoring data of the limited monitoring devices. The voltage sag state in the present disclosure is a voltage sag amplitude and voltage sag duration in a single sag event.

Sudden voltage sag change point: It is a point at which a voltage amplitude in an effective value waveform of a voltage sag suddenly changes significantly (beyond a normal voltage fluctuation range). The sudden voltage sag change point is formed in the case of the short circuit fault, disconnection of the DG device from the power grid after the short circuit fault, and action of a relay protection device on one side of the faulty line after the short circuit fault. The sudden voltage sag change point can be determined through waveform point detection.

### SUMMARY

To resolve the above problems, the present disclosure provides a state estimation method for a multi-stage voltage sag to analyze characteristics of multi-stage voltage sags due to different causes, consider the sudden change time of each stage and fault clearing time of a relay protection device in the monitoring data of the multi-stage voltage sag, infer a specific event that may occur in each stage of the multi-stage voltage sag, and finally obtain a multi-stage state estimation method that meets project requirements. The technical solutions are as follows:

A state estimation method for a multi-stage voltage sag includes the following steps:
Step 1: analyzing the causes of a multi-stage voltage sag, determining characteristics of multi-stage voltage sags due to different causes, and identifying causes of voltage sags at different sudden change points accordingly;
Step 2: building an action matrix of a relay protection device based on specified fault clearing time at different positions of a power grid;
Step 3: obtaining one or more possible faulty lines by solving to form a faulty line set to reduce the calculation amount of state estimation of the multi-stage voltage sag;
Step 4: calculating system impedance matrices before and after a fault, an impedance matrix in the case of a relay protection action on one side of the faulty line, and an impedance matrix when a DG device is disconnected from the power grid;
Step 5: using an optimization model to infer a specific faulty line from the faulty line set obtained in step 3 and inferring a specific event of each stage of the multi-stage voltage sag based on a voltage sag type; and
Step 6: estimating the duration of each sag stage based on the voltage sag type and the time length between adjacent sudden voltage sag change points and estimating a sag amplitude based on an event inference result in step 5.

Further, in step 1, the causes and corresponding characteristics of the multi-stage voltage sag are as follows:

Cause I: During a short circuit fault, one or more DG devices are in a power system trip, resulting in a loss of a power supply of the power grid. The corresponding characteristic is that a voltage amplitude on the right side of a corresponding sudden voltage sag change point when the voltage sag occurs is smaller than that on the left side.

Cause II: During the short circuit fault, relay protection devices on two sides of the faulty line trip at different times, resulting in a change in the topology of the power grid. The corresponding characteristic is that the voltage amplitude on the right side of the corresponding sudden voltage sag change point when the voltage sag occurs is greater than that on the left side.

Further, the identifying causes of voltage sags at different sudden change points specifically comprises:

Assuming that for a waveform segment containing the voltage sag, a total of s+1 sudden voltage sag change points are detected by using a waveform point detection method, which is respectively expressed as MP₀, MP₁,...,MPₓ,...,MPₛ and correspond to s + 1 sudden change time points t₀, t₁,..., tₓ,..., ts, these sudden voltage sag change points divide a waveform of the voltage sag into ^{S} segments. Voltages of the different waveform segments are respectively expressed as u₁, u₂,...,uₓ,...,uₛ, and an ^{m}^{th} voltage uₘ is calculated as follows:

$${u}_{m} = {\sum }_{j = f f * \left({t}_{m - 1} + 1 / f\right)}^{j = f f * {t}_{m}} {x}_{j} / \left(\left({t}_{m} - {t}_{m - 1} + 1 / f\right) * f f\right) ; j ∈ \left[1 , k\right] ,$$

Where ff represents a sampling rate in units of piece/second, f represents a power-frequency current frequency in units of Hz, xⱼ represents a j ^{th} value in an effective value sequence, m ∈ [1, s], and k represents a total quantity of sampling points.

A binary vector W is formed:

$$\left\{\begin{matrix}W = \left[{w}_{1} , {w}_{2} , \text{L} \text{,} {w}_{x} , \text{L} , {w}_{s}\right] , x ∈ \left[1 , s\right] \\ {w}_{x} = \left\{\begin{matrix}0 , \text{if} {u}_{x} < {u}_{x - 1} \text{or} x = 1 \\ 1 , \text{if} {u}_{x} > {u}_{x - 1}\end{matrix}\right)\end{matrix}\right) .$$

The value of the element Wₓ in the vector W is 0 or 1. When the value of the Wₓ is 0, it indicates that the voltage on a right side of MPₓ₋₁ corresponding to a time point tₓ₋₁ is less than that on the left side, which means that the multi-stage voltage sag is formed due to the cause I at this time point, where x > 1. On the contrary, when the value of the wₓ is 1, it means that the multi-stage voltage sag is formed due to the cause II at the time point tₓ₋₁, where x > 1.

Further, the building of an action matrix of a relay protection device in step 2 specifically includes:

Step 2.1: building a basic action matrix, in other words, a universal matrix describing the fault removal behavior of the relay protection device is built:

$$\text{Γ=} \left(\begin{matrix}0 & {γ}_{12} & {γ}_{13} & \text{L} & {γ}_{1 n} \\ {γ}_{21} & 0 & {γ}_{23} & \text{L} & {γ}_{2 n} \\ {γ}_{31} & {γ}_{32} & 0 & \text{O} & \text{M} \\ \text{M} & \text{M} & \text{O} & 0 & {γ}_{\left(n - 1\right) n} \\ {γ}_{n 1} & {γ}_{n 2} & \text{L} & {γ}_{n \left(n - 1\right)} & 0\end{matrix}\right) ,$$

Where n represents the quantity of buses in the system; ^{γ}ᵢⱼ and ^{γ}ⱼᵢ respectively represent the fault clearing time of protection devices close to i -side and j -side buses on a line lᵢⱼ in which i, j ∈ [1, n]; i ≠ j ; ^{γ}ᵢⱼ, ^{γ}ⱼᵢ = 0 represents that there is no physical connection between the i -side bus and the j -side bus.

Step 2.2: improving the universal matrix and decoupling an improved universal matrix into two matrices:

$$\text{Γ} \tilde{\text{Ν}} \text{=} \left(\begin{matrix}0 & 0 & 0 & \text{0} & 0 \\ {γ}_{21} & 0 & 0 & \text{0} & 0 \\ {γ}_{31} & {γ}_{32} & 0 & \text{0} & \text{0} \\ \text{M} & \text{M} & \text{O} & 0 & 0 \\ {γ}_{n 1} & {γ}_{n 2} & \text{L} & {γ}_{n \left(n - 1\right)} & 0\end{matrix}\right) \text{and}$$

$$\text{ΓΔ=} \left(\begin{matrix}0 & {γ}_{12} & {γ}_{13} & \text{L} & {γ}_{n 1} \\ 0 & 0 & {γ}_{23} & \text{L} & {γ}_{n 2} \\ 0 & 0 & 0 & \text{O} & \text{M} \\ \text{0} & \text{0} & \text{0} & 0 & {γ}_{n \left(n - 1\right)} \\ 0 & 0 & \text{0} & 0 & 0\end{matrix}\right) .$$

The upper and lower triangular matrices respectively represent fault clearing time of protective devices of the same type on two terminal buses of the line. The lower triangular element in the lower triangular matrix represents the fault clearing time of the protection device of the i -side bus of the line lᵢⱼ, and ^{γ}ᵢⱼ = 0 and i > j represent that there is no physical connection between the i -side bus and the j -side bus. The upper triangular element in the upper triangular matrix represents a parameter on the other side of the line.

To represent two-stage protection, two other similar matrices are constructed to represent the parameters of backup protection:

$$\text{Λ} \tilde{\text{Ν}} \text{=} \left(\begin{matrix}0 & 0 & 0 & \text{0} & 0 \\ {λ}_{21} & 0 & 0 & \text{0} & 0 \\ {λ}_{31} & {λ}_{32} & 0 & \text{0} & \text{0} \\ \text{M} & \text{M} & \text{O} & 0 & 0 \\ {λ}_{n 1} & {λ}_{n 2} & \text{L} & {λ}_{n \left(n - 1\right)} & 0\end{matrix}\right) \text{and}$$

$$\text{ΛΔ=} \left(\begin{matrix}0 & {λ}_{12} & {λ}_{13} & \text{L} & {λ}_{1 n} \\ 0 & 0 & {λ}_{23} & \text{L} & {λ}_{2 n} \\ 0 & 0 & 0 & \text{O} & \text{M} \\ \text{0} & \text{0} & \text{0} & 0 & {λ}_{n \left(n - 1\right)} \\ 0 & 0 & \text{0} & 0 & 0\end{matrix}\right) .$$

Step 2.3: determining a cooperation relationship of the protection devices:

For the two-stage protection, there are four cooperation relationships between the main protection and the backup protection in the line, and the improved protection action matrix is expressed as the following cooperation relationships:

$$\text{Γ} \tilde{\text{N}} + \text{ΓΔ=} {\text{Θ}}_{\text{I}} ,$$

$$\text{Γ} \tilde{\text{N}} + \text{ΛΔ=} {\text{Θ}}_{\text{II}} ,$$

$$\text{Λ} \tilde{\text{N}} + \text{ΛΔ=} {\text{Θ}}_{\text{III}} , \text{and}$$

$$\text{Λ} \tilde{\text{N}} + \text{ΓΔ=} {\text{Θ}}_{\text{IV}} .$$

Where Θ_{I} represents that the main protection on the two sides of the faulty line cooperates to remove the fault; Θ_{II} represents that the backup protection on the two sides of the faulty line cooperates to remove the fault; Θ_{III} and Θ_{IV} represent that the main protection on one side of the faulty line cooperates with the backup protection on the other side of the faulty line to remove the fault.

Step 2.4: correcting fault clearing time in the action matrix:

The fault clearing time is corrected as follows:

$$\left\{\begin{matrix}{γ}_{i j} = {γ}_{i j , s e t} + {δ}_{1 , i j} \\ {λ}_{i j} = {λ}_{i j , s e t} + {δ}_{2 , i j}\end{matrix} ; i , j ∈ \left[1 , n\right] ; i \neq j .\right)$$

Where ^{γ}ᵢⱼ, ₛₑₜ and ^{λ}ᵢⱼ,ₛₑₜ respectively represent specified values of the main protection and the backup protection; ^{δ}₁,ᵢⱼ and ^{δ}₂,ᵢⱼ respectively represent deviations between actual fault clearing time and the specified values; and the deviations are random numbers within [0, δ], where δ represents a maximum error value during the testing or historical operation of relay protection devices of the same model.

Further, step 3 specifically includes steps 3.1 and 3.2.

Step 3.1: defining the following four voltage sag types based on the sag cause identification in step 1:
Type I: single-stage rectangular sag,
Type II: multi-stage voltage sag due to cause I,
Type III: multi-stage voltage sag due to cause II, and
Type IV: multi-stage voltage sag due to cause I and cause II.

Step 3.2: obtaining the faulty line set for different types of sags.

For type I and type II:

Assuming that time points at which first and last sudden voltage sag change points of the waveform of the voltage sag are detected in step 1 are t₀ and tₛ respectively, a time length from the occurrence of the fault to removal of the fault in the system is tₛ -t₀. If two elements of symmetric positions of a main diagonal line of a matrix in the four matrices in step 2.3 are equal to tₛ -t₀ within an error threshold, lines corresponding to these two elements are possible faulty lines, and therefore, a solution model of the faulty line set LF is as follows:

$$\left\{\begin{matrix}L F = \left\{\text{L} , {l}_{i j} , \text{L}\right\} \\ \text{s} . \text{t} . L F ⊆ L N \\ \sqrt{\left|{θ}_{i j} - \left({t}_{s} - {t}_{0}\right)\right| + \left|{θ}_{i j} - \left({t}_{s} - {t}_{0}\right)\right|} \leq \\ \sqrt{max \left({δ}_{1 , i j} , {δ}_{1 , j i}\right) + max \left({δ}_{2 , i j} , {δ}_{2 , j i}\right)} \leq \sqrt{2 δ} \\ i , j ∈ \left[1 , n\right] ; i \neq j\end{matrix}\right) ,$$

Where ^{θ}ᵢⱼ represents an element in an i ^{th} row and a j ^{th} column in the matrices Θ_{I} to Θ_{IV}, and LN represents a set of lines in an intersection of sag domains of a bus of a monitoring device.

For type III and type IV:

Assuming that the time point at which the first sudden voltage sag change point of the waveform of the voltage sag is detected in step 1 is t₀ and time points of sudden voltage sag change points of two corresponding relay protection actions are tₓ₋₁ and tₛ respectively, a time length from the occurrence of the fault to the protection actions of the relay protection devices on the two sides of the faulty line are tₓ₋₁-t₀ and tₛ -t₀ respectively. In this case, the solution model of the faulty line set is as follows:

$$\left\{\begin{matrix}L F = \left\{\text{L} , {l}_{i j} , \text{L}\right\} \\ \text{s} . \text{t} . L F ⊆ L N \\ \sqrt{\left|{θ}_{i j} - \left({t}_{x - 1} - {t}_{0}\right)\right| + \left|{θ}_{i j} - \left({t}_{s} - {t}_{0}\right)\right|} \leq \\ \sqrt{max \left({δ}_{1 , i j} , {δ}_{1 , j i}\right) + max \left({δ}_{2 , i j} , {δ}_{2 , j i}\right)} \leq \sqrt{2 δ} \\ i , j ∈ \left[1 , n\right] ; i \neq j ; s \geq 2 ; {w}_{x} = 1\end{matrix}\right) .$$

Further, step 4 specifically includes steps 4.1, 4.2, 4.3, and 4.4.

Step 4.1: calculating the system impedance matrix before the fault:

A system admittance ₘₐₜᵣiₓ Y^{SE} is expressed as a sum of a line admittance matrix

$${Y}_{L}^{S E}$$

and a generator admittance matrix

$${Y}_{G}^{S E}$$

, as shown below:

$${Y}^{S E} = {Y}_{G}^{S E} + {Y}_{L}^{S E} .$$

Assuming there are ⁿ buses in the power system, the line admittance matrix

$${Y}_{L}^{S E}$$

is calculated as follows based on a line topology relationship and an impedance parameter:

$${Y}_{L}^{S E} = \left(\begin{matrix}{α}_{11}^{s e} & {α}_{12}^{s e} & \text{L} & {α}_{1 n}^{s e} \\ {α}_{21}^{s e} & {α}_{22}^{s e} & \text{L} & {α}_{2 n}^{s e} \\ \text{M} & \text{M} & \text{O} & \text{M} \\ {α}_{n 1}^{s e} & {α}_{n 2}^{s e} & \text{L} & {α}_{n n}^{s e}\end{matrix}\right) ,$$

Where se = 1,2,0 represents a positive sequence, a negative sequence, and a zero sequence, ^{α}ᵢⱼ represents mutual admittance of nodes i and j, ^{α}ᵢᵢ represents self-admittance of the node i, and i ≠ j; i, j ∈ [1, n] .

The matrix

$${Y}_{G}^{S E}$$

is a diagonal matrix, and an element value on a diagonal line is equal to the self-admittance of a corresponding generator, as shown below:

$${Y}_{G}^{S E} = \left(\begin{matrix}{β}_{11}^{s e} & 0 & \text{L} & 0 \\ 0 & {β}_{22}^{s e} & \text{L} & 0 \\ \text{M} & \text{M} & \text{O} & \text{M} \\ 0 & 0 & \text{L} & {β}_{n n}^{s e}\end{matrix}\right) .$$

Where βᵢᵢ = 0 represents that there is no generator for the bus.

The system impedance matrix is calculated as follows:

$${Z}_{n}^{S E} = {\left({Y}_{G}^{S E}\right)}^{- 1} = \left(\begin{matrix}{Z}_{11}^{s e} & {Z}_{12}^{s e} & \text{L} & {Z}_{1 n}^{s e} \\ {Z}_{21}^{s e} & {Z}_{22}^{s e} & \text{L} & {Z}_{2 n}^{s e} \\ \text{M} & \text{M} & \text{O} & \text{M} \\ {Z}_{n 1}^{s e} & {Z}_{n 2}^{s e} & \text{L} & {Z}_{n n}^{s e}\end{matrix}\right) .$$

Step 4.2: calculating the system impedance matrix after the short circuit fault:

Mutual impedance

$${Z}_{m f}^{s e}$$

between a fault position fₗ and a to-be-solved node ^{m} after the circuit short fault, and self-impedance

$${Z}_{f f}^{s e}$$

of the fault position fₗ are respectively obtained by solving the following two formulas:

$${Z}_{m f}^{s e} = \left(1 - p\right) {Z}_{m i}^{s e} + p {Z}_{m j}^{s e} = {g}_{m f 1} \left(i , j , p\right) , \text{and}$$

$${Z}_{f f}^{s e} = \left\{\begin{matrix}{\left(1 - p\right)}^{2} {Z}_{i i}^{s e} + {p}^{2} {Z}_{j j}^{s e} + \\ 2 p \left(1 - p\right) {Z}_{i j}^{s e} + p \left(1 - p\right) {z}_{i j}^{s e}\end{matrix}\right\} = {g}_{f f 1} \left(i , j , p\right) .$$

Where

$${Z}_{m i}^{s e} , {Z}_{m j}^{s e} , {Z}_{i j}^{s e} , {Z}_{i i}^{s e} , \text{and} {Z}_{j j}^{s e}$$

are elements in the matrix

$${z}_{i j}^{s e}$$

represents impedance of the line ^{l}ᵢⱼ, where the impedance is further expressed as functions g_{mf1} (i, j, p) and g _{ff1} (i, j, p). The two functions g_{mf1} (i, j, p) and g _{ff1} (i, j, p) respectively represent mutual impedance between the fault position and the target node ^{m} and self-impedance of the fault position when the short circuit fault occurs at the position fₗ having a distance P away from the i -side of the line ^{l}ᵢⱼ .

Step 4.3: calculating the impedance matrix in the case of the relay protection action on one side of the faulty line:

Assuming that after the short circuit fault occurs on the line lᵢⱼ, a j -side protection device acts to cut off the line on the corresponding side, and the system impedance is calculated as follows:

First, a branch with impedance of -zᵢⱼ is added between the i -side bus and the j -side bus in the original system. In this case, the system impedance matrix

$${Z}_{A T}^{S E}$$

is corrected according to the following formula:

$$\begin{matrix}{Z}_{A T}^{S E} = {Z}_{N}^{S E} - \frac{\text{Δ} Z \text{Δ} {Z}^{T}}{- {z}_{i j}^{s e} + {Z}_{i i}^{s e} + {Z}_{j j}^{s e} - 2 {Z}_{i j}^{s e}} \\ = \left(\begin{matrix}{Z}_{11 , \text{AT}}^{s e} & {Z}_{12 , \text{AT}}^{s e} & \text{L} & {Z}_{1 n , \text{AT}}^{s e} \\ {Z}_{21 , \text{AT}}^{s e} & {Z}_{22 , \text{AT}}^{s e} & \text{L} & {Z}_{2 n , \text{AT}}^{s e} \\ \text{M} & \text{M} & \text{O} & \text{M} \\ {Z}_{n 1 , \text{AT}}^{s e} & {Z}_{n 2 , \text{AT}}^{s e} & \text{L} & {Z}_{n n , \text{AT}}^{s e}\end{matrix}\right) .\end{matrix}$$

Where ΔZ represents a process quantity, which is calculated according to the following formula:

$$\text{Δ} Z = {\left[\begin{matrix}{Z}_{1 j}^{s e} - {Z}_{1 i}^{s e} & {Z}_{2 j}^{s e} - {Z}_{2 i}^{s e} & ⋯ & {Z}_{n j}^{s e} - {Z}_{n i}^{s e}\end{matrix}\right]}^{\text{T}} .$$

Subsequently, a branch with impedance of pzᵢⱼ is added to the i -side bus. In this case, the system impedance matrix is further corrected as

$${Z}_{A R P}^{S E}$$

according to the following formula:

$${Z}_{A R P}^{S E} = \left(\begin{matrix}{Z}_{11 , A T}^{s e} & {Z}_{11 , A T}^{s e} & L & {Z}_{11 , A T}^{s e} & {Z}_{11 , A T}^{s e} \\ {Z}_{11 , A T}^{s e} & {Z}_{11 , A T}^{s e} & L & {Z}_{11 , A T}^{s e} & {Z}_{11 , A T}^{s e} \\ M & M & O & M & M \\ {Z}_{11 , A T}^{s e} & {Z}_{11 , A T}^{s e} & L & {Z}_{11 , A T}^{s e} & {Z}_{11 , A T}^{s e} \\ {Z}_{11 , A T}^{s e} & {Z}_{11 , A T}^{s e} & L & {Z}_{11 , A T}^{s e} & {Z}_{11 , A T}^{s e} + p {z}_{i j}\end{matrix}\right)$$

Compared with the

$${Z}_{A T}^{S E} ,$$

the

$${Z}_{A R P}^{S E}$$

adds one line and one column to represent the mutual impedance

$${Z}_{m f}^{s e}$$

between the fault position fₗ and each target bus ^{m} or the self-impedance

$${Z}_{f f}^{s e}$$

of the fault position. The impedance is further expressed as functions g_{mf 2} (i, j, p, d) and g_{ff 2} (i, j, p, d), where the two functions respectively represent mutual impedance between the fault position and the target node ^{m} and self-impedance of the fault position when a d -side protection device on the line acts to cut off a part of the line after the short circuit fault occurs at the position fₗ far from the terminal P of the node i on the line lᵢⱼ, as shown in the following formulas:

$${Z}_{m f}^{s e} = {Z}_{i m , \text{AT}}^{s e} = {g}_{m f 2} \left(i , j , p , d\right) ; d = i \text{or} j \text{and}$$

$${Z}_{f f}^{s e} = {Z}_{i i , \text{AT}}^{s e} + p {z}_{i j} = {g}_{f f 2} \left(i , j , p , d\right) ; d = i \text{or} j .$$

Step 4.4: calculating the impedance matrix when the DG device is disconnected from the power grid:

Assuming that DG devices of all buses in a bus set h are disconnected from the power grid, the diagonal matrix first needs to be corrected as follows:

$${Y}_{G}^{S E} = \left(\begin{matrix}{β}_{11}^{s e} & 0 & \text{L} & 0 \\ 0 & {β}_{22}^{s e} & \text{L} & 0 \\ \text{M} & \text{M} & \text{O} & \text{M} \\ 0 & 0 & \text{L} & {β}_{n n}^{s e}\end{matrix}\right) ; {β}_{i i}^{s e} = 0 ; ∀ i ∈ h .$$

The system impedance matrix before the fault is calculated according to the above formula. Finally, system impedance when the DG device is disconnected from the power grid in the case of the short circuit fault is calculated. The impedance is further expressed as functions g_{mf 3} (i, j, p, h) and g _{ff3} (i, j, p, h), where the two functions respectively represent mutual impedance between the fault position and the target node ^{m} and self-impedance of the fault position after the short circuit fault occurs at the position fₗ far from the terminal P of the node i on the line lᵢⱼ, and the DG devices of all the buses in the bus set h are disconnected from the power grid, as shown in the following two formulas:

$${Z}_{m f}^{s e} = {g}_{m f 3} \left(i , j , p , h\right) \text{and}$$

$${Z}_{f f}^{s e} = {g}_{f f 3} \left(i , j , p , h\right) .$$

Further, in step 5, the following four optimization models are available based on the sag types:

(1) For type I, the following optimization model is used to infer the faulty line and its short circuit condition using the variables i, j, and P :

$$\left\{\begin{matrix}max \text{-} \sqrt{\left|f \left({g}_{m f 1} \left(i , j , p\right) , {g}_{f f 1} \left(i , j , p\right)\right)\right| - {u}_{1}} \\ \text{s} \text{.t} \text{.} i , j ∈ \left[1 , n\right] ; i \neq j\end{matrix}\right) ,$$

where f (·) represents a short-circuit calculation function.

(2) For type II, the following optimization model is used to infer the faulty line and its short circuit condition and a time point and a sequence of disconnecting the DG device from the power grid using the variables i, j, p, and ^{h}_{q}:

$$\left\{\begin{matrix}max \text{-} \left(\begin{matrix}\sqrt{\left|f \left({g}_{m f 1} \left(i , j , p\right) , {g}_{f f 1} \left(i , j , p\right)\right)\right| - {u}_{1}} + \\ {\sum }_{x = 2}^{s} {\sum }_{q = 1}^{s - 1} \sqrt{\left|f \left({g}_{m f 3} \left(i , j , p , {h}_{q}\right) , {g}_{f f 3} \left(i , j , p , {h}_{q}\right)\right)\right| - {u}_{x}}\end{matrix}\right) \\ \text{s} \text{.t} \text{.} i , j ∈ \left[1 , n\right] ; i \neq j ; {h}_{1} ⊆ {h}_{2} ⊆ ⋯ ⊆ {h}_{s \text{-1}}\end{matrix}\right) ,$$

where ^{s} represents a quantity of stages of the multi-stage voltage sag and ^{h}_{q} represents a set of DG devices disconnected from the power grid during a q-stage voltage sag.

(3) For type III, the following optimization model is used to infer the faulty line and its short circuit condition and a tripping time point and sequence of the relay protection device using the variables i, j, p, and d :

$$\left\{\begin{matrix}max \text{-} \left(\begin{matrix}\sqrt{\left|f \left({g}_{m f 1} \left(i , j , p\right) , {g}_{f f 1} \left(i , j , p\right)\right)\right| - {u}_{1}} + \\ \sqrt{\left|f \left({g}_{m f 2} \left(i , j , p , d\right) , {g}_{f f 2} \left(i , j , p , d\right)\right)\right| - {u}_{2}}\end{matrix}\right) \\ \text{s} \text{.t} \text{.} i , j ∈ \left[1 , n\right] ; i \neq j\end{matrix}\right) .$$

(4) For type IV, the following optimization model is used to infer the faulty line and its short circuit condition, the tripping time point and sequence of the relay protection device, and the time point and the sequence of disconnecting the DG device from the power grid using the variables i, j, p, d, and ^{h}_{q} :

$$\left\{\begin{matrix}max \text{-} \left(\begin{matrix}\begin{matrix}\sqrt{\left|f \left({g}_{m f 1} \left(i , j , p\right) , {g}_{f f 1} \left(i , j , p\right)\right)\right| - {u}_{1}} + \\ {\sum }_{x = 2}^{o} {\sum }_{q = 1}^{o - 1} \sqrt{\left|f \left({g}_{m f 3} \left(i , j , p , {h}_{q}\right) , {g}_{f f 3} \left(i , j , p , {h}_{q}\right)\right)\right| - {u}_{x}}\end{matrix} \\ \begin{matrix}+ \left|f \left({g}_{m f 2} \left(i , j , p , d\right) , {g}_{f f 2} \left(i , j , p , d\right)\right)\right| - {u}_{o + 1} + \\ {\sum }_{x = o + 2}^{s} {\sum }_{h = o}^{s - 2} \sqrt{\left|f \left({g}_{m f 3} \left(i , j , p , {h}_{q}\right) , {g}_{f f 3} \left(i , j , p , {h}_{q}\right)\right)\right| - {u}_{x}}\end{matrix}\end{matrix}\right) \\ \text{s} \text{.t} \text{.} i , j ∈ \left[1 , n\right] ; i \neq j ; {h}_{1} ⊆ {h}_{2} ⊆ ⋯ ⊆ {h}_{s \text{-2}}\end{matrix}\right) .$$

Where o represents a time point at which a relay protection device on the side of the faulty line first acts to trip and ^{u}₀₊₁ represents an amplitude of an o+1-stage voltage sag.

Further, in step 6, the following four voltage sag estimation methods are available based on the sag types:

1) For type I, a sag amplitude of any unmonitored bus ^{m} is estimated according to the following formula:

$$f \left({g}_{m f 1} \left(i , j , p\right) , {g}_{f f 1} \left(i , j , p\right)\right) .$$

2) For type II, a sag amplitude of any unmonitored bus ^{m} is estimated according to the following formula:

$$\left\{\begin{matrix}{u}_{1} = f \left({g}_{m f 1} \left(i , j , p\right) , {g}_{f f 1} \left(i , j , p\right)\right) \\ {u}_{x} = f \left({g}_{m f 3} \left(i , j , p , {h}_{x - 1}\right) , {g}_{f f 3} \left(i , j , p , {h}_{x - 1}\right)\right)\end{matrix}\right) .$$

3) For type III, a sag amplitude of any unmonitored bus ^{m} is estimated according to the following formula:

$$\left\{\begin{matrix}{u}_{1} = f \left({g}_{m f 1} \left(i , j , p\right) , {g}_{f f 1} \left(i , j , p\right)\right) \\ {u}_{2} = f \left({g}_{m f 2} \left(i , j , p , d\right) , {g}_{f f 2} \left(i , j , p , d\right)\right)\end{matrix}\right) .$$

4) For type IV, a sag amplitude of any unmonitored bus ^{m} is estimated according to the following formula:

$$\left\{\begin{matrix}{u}_{1} = f \left({g}_{m f 1} \left(i , j , p\right) , {g}_{f f 1} \left(i , j , p\right)\right) \\ {u}_{x} = f \left({g}_{m f 3} \left(i , j , p , {h}_{x - 1}\right) , {g}_{f f 3} \left(i , j , p , {h}_{x - 1}\right)\right) \\ {u}_{y} = f \left({g}_{m f 2} \left(i , j , p , d\right) , {g}_{f f 2} \left(i , j , p , d\right)\right) \\ {u}_{z} = f \left({g}_{m f 3} \left(i , j , p , {h}_{z - 1}\right) , {g}_{f f 3} \left(i , j , p , {h}_{z - 1}\right)\right) \\ x ∈ \left[2 , y - 1\right] ; z ∈ \left[y + 1 , s - 2\right]\end{matrix}\right) ,$$

Where ^{y} and z respectively represent y^{th} and z^{th} stages of the multi-stage voltage sag.

The present disclosure has the following beneficial effects:

1) The present disclosure analyzes characteristics of multi-stage voltage sags due to different causes and proposes a method for determining a cause of sudden change time of an amplitude of the multi-stage voltage sag based on a jump characteristic of the sag amplitude.

2) The present disclosure proposes calculation methods of a relay protection action matrix and a faulty line set to preliminarily obtain a faulty line set based on fault clearing time of a relay protection device and other characteristics to effectively reduce the calculation amount of sag state estimation.

3) Based on a substantive characteristic that different events cause a change of system impedance, the present disclosure proposes a method for inferring a cause of an event in each stage of the multi-stage voltage sag to improve the accuracy of the state estimation.

4) Based on a cause inference result of the event, the present disclosure proposes a state estimation method for the multi-stage voltage sag to resolve the problem that it is difficult to apply an existing state estimation method to the multi-stage voltage sag.

### BRIEF DESCRIPTION OF THE DRAWINGS

FIG. 1 shows a short-circuit calculation model of a power system;

FIG. 2 shows a short-circuit calculation model of a power system after a faulty line is cut off on one side according to the present disclosure; and

FIG. 3 is a process of building a state estimation model of a multi-stage voltage sag according to the present disclosure.

### DETAILED DESCRIPTION OF THE EMBODIMENTS

The present disclosure will be further described below in conjunction with the accompanying drawings and specific embodiments.

The technical solution of the present disclosure is mainly divided into six steps: identifying causes of a multi-stage voltage sag, building an action matrix of a relay protection device, obtaining a faulty line set by solving equations, obtaining an impedance matrix by solving equations, and inferring a specific event at each stage of the multi-stage voltage sag and a state estimation method for the multi-stage voltage sag. Details of each step and its substeps are as follows:

1. The causes of the multi-stage voltage sag are identified.

### There Are Two Causes of the Multi-Stage Voltage Sag

Cause 1: During a short circuit fault, one or more DG device are in a power system trip, resulting in a loss of a power supply from a power grid.

Cause 2: During the short circuit fault, relay protection devices on two sides of a faulty line trip at different times, resulting in a change of the topology of the power grid.

### Characteristics of Multi-Stage Voltage Sags Due to Different Causes

Cause 1 means that after the fault, the system further loses the power supply, so a monitored voltage sag amplitude is further reduced. The corresponding characteristic is that a voltage amplitude on a right side of the corresponding sudden voltage sag change point when cause 1 occurs is smaller than that on a left side.

On the contrary, cause 2 means that after the fault occurs, a protection device on one side of the line partially isolates the fault from the system, so the monitored voltage sag amplitude increases. The corresponding characteristic is that a voltage amplitude on the right side of the corresponding sudden voltage sag change point when the cause 2 occurs is greater than that on the left side.

### Cause Identification of Voltage Sags at Different Sudden Change Points

It is assumed that for a waveform segment containing the voltage sag, a total of s+1 sudden voltage sag change points are detected by using a waveform point detection method, which are respectively expressed as MP₀,MP₁,...,MPₓ,...,MPₛ and correspond to s +1 sudden change time points t₀, t₁,..., tₓ,..., tₛ . These sudden voltage sag change points divide a waveform of the voltage sag into ^{S} segments. Voltages of different waveform segments are respectively expressed as ^{u}₁, ^{u}₂, .. .,^{u}ₓ,.. ., u_{s,} and an m (m ∈ [1, s]) ^{th} voltage uₘ can be calculated as follows:

$${u}_{m} = {\sum }_{j = f f * \left({t}_{m - 1} + 1 / f\right)}^{j = f f * {t}_{m}} {x}_{j} / \left(\left({t}_{m} - {t}_{m - 1} + 1 / f\right) * f f\right) ; j ∈ \left[1 , k\right] \qquad \text{(7)}$$

In the above formula, ff represents a sampling rate in units of piece/second, f represents a power-frequency current frequency in units of Hz, and ^{x}ⱼ represents a j ^{th} value in an effective value sequence. Binary vector W shown in formula (8) can be formed according to the formula (7):

$$\left\{\begin{matrix}W = \left[{w}_{1} , {w}_{2} , \text{L} \text{,} {w}_{x} , \text{L,} {w}_{s}\right] , x ∈ \left[1 , s\right] \\ {w}_{x} = \left\{\begin{matrix}0 , \text{if} {u}_{x} < {u}_{x - 1} \text{or} x = 1 \\ 1 , \text{if} {u}_{x} > {u}_{x - 1}\end{matrix}\right)\end{matrix}\right) \qquad \text{(8)}$$

The value of the element wₓ in the vector W is 0 or 1. When the value is 0, it indicates that a voltage on a right side of MPₓ₋₁ corresponding to time point tₓ₋₁ (x > 1) is less than that on a left side, which means that the multi-stage voltage sag is formed due to cause 1 at this time point. On the contrary, when the value is 1, it means that the multi-stage voltage sag is formed due to cause 2 at the time point tₓ₋₁ (x > 1).

2. Action matrix of the relay protection device.

Actual tripping time of the relay protection device in a sag event can be roughly obtained based on multi-stage voltage sag causes at time points corresponding to different sudden voltage sag change points. In order to use the information, a method for building the action matrix of the relay protection device based on specified fault clearing time at different positions of the power grid is proposed in step 2.

### Basic Action Matrix

There are different types of relay protection, including low-voltage protection, over-current protection, and distance protection. Each type of protection has its own trigger rule and fault clearing time to clear the fault. The present disclosure provides a universal matrix for describing a fault removal behavior of the relay protection device, as shown in the following formula:

$$\text{Γ=} \left(\begin{matrix}0 & {γ}_{12} & {γ}_{13} & \text{L} & {γ}_{1 n} \\ {γ}_{21} & 0 & {γ}_{23} & \text{L} & {γ}_{2 n} \\ {γ}_{31} & {γ}_{32} & 0 & \text{O} & \text{M} \\ \text{M} & \text{M} & \text{O} & 0 & {γ}_{\left(n - 1\right) n} \\ {γ}_{n 1} & {γ}_{n 2} & \text{L} & {γ}_{n \left(n - 1\right)} & 0\end{matrix}\right) \qquad \text{(9)}$$

Where n represents a quantity of buses in the system, ^{γ}ᵢⱼ and ^{γ}ⱼᵢ (i, j ∈ [1, n]; i ≠ j) respectively represent fault clearing time of protection devices close to i -side and j -side buses on line lᵢⱼ in units of ms, and ^{γ}ᵢⱼ, ^{γ}ⱼᵢ= 0 represents that there is no physical connection between the i -side bus and the j -side bus. The fault clearing time is a specified value of the relay protection device recorded in the software of a power distribution automation system and other power enterprises.

### The Action Matrix is Improved

In practical application, staged protection is widely used in a power distribution system, such as two-stage protection. The two-stage protection means that two types of protection are provided on one line, namely, main protection and backup protection. The two types of protection have different fault clearing time, and the main protection has shorter fault clearing time. When the short circuit fault occurs, the main protection is triggered first, and the backup protection works when the main protection cannot be triggered. In general, the fault can be removed by the main protection independently, and sometimes may be removed by the backup protection independently or by both the main protection and the backup protection. Considering that it is difficult for the basic action matrix defined in the formula (9) to present a cooperation relationship of the staged protection, the present disclosure improves the basic action matrix and decouples an improved basic action matrix into two matrices, as shown in equations (10) and (11):

$$\text{Γ} \tilde{\text{N}} \text{=} \left(\begin{matrix}0 & 0 & 0 & 0 & 0 \\ {γ}_{21} & 0 & 0 & 0 & 0 \\ {γ}_{31} & {γ}_{32} & 0 & 0 & 0 \\ \text{M} & \text{M} & \text{O} & 0 & 0 \\ {γ}_{n 1} & {γ}_{n 2} & \text{L} & {γ}_{n \left(n - 1\right)} & 0\end{matrix}\right) \qquad \text{(10)}$$

$$\text{ΓΔ=} \left(\begin{matrix}0 & {γ}_{12} & {γ}_{13} & \text{L} & {γ}_{1 n} \\ 0 & 0 & {γ}_{23} & \text{L} & {γ}_{2 n} \\ 0 & 0 & 0 & \text{O} & \text{M} \\ 0 & 0 & 0 & 0 & {γ}_{\left(n - 1\right) n} \\ 0 & 0 & 0 & 0 & 0\end{matrix}\right) \qquad \text{(11)}$$

In the above formulas, the upper and lower triangular matrices respectively represent fault clearing time of protection devices of the same type on two terminal buses of the line. The lower triangular element in the lower triangular matrix represents the fault clearing time of the protection device of the i -side bus of the line lᵢⱼ, and ^{γ}ᵢⱼ = 0(i > j) represents that there is no physical connection between the i -side bus and the j -side bus. The upper triangular element in the upper triangular matrix represents a parameter on the other side of the line, which has a similar meaning. The formulas (10) and (11) represent parameters of the main protection. To represent the two-stage protection, two other similar matrices are constructed to represent parameters of the backup protection, as shown in formulas (12) and (13):

$$\text{Λ} \tilde{\text{N}} = \left(\begin{matrix}0 & 0 & 0 & 0 & 0 \\ {λ}_{21} & 0 & 0 & 0 & 0 \\ {λ}_{31} & {λ}_{32} & 0 & 0 & 0 \\ \text{M} & \text{M} & \text{O} & 0 & 0 \\ {λ}_{n 1} & {λ}_{n 2} & \text{L} & {λ}_{n \left(n - 1\right)} & 0\end{matrix}\right) \qquad \text{(12)}$$

$$\text{ΛΔ} = \left(\begin{matrix}0 & {λ}_{12} & {λ}_{13} & \text{L} & {λ}_{1 n} \\ 0 & 0 & {λ}_{23} & \text{L} & {λ}_{2 n} \\ 0 & 0 & 0 & \text{O} & \text{M} \\ 0 & 0 & 0 & 0 & {λ}_{\left(n - 1\right) n} \\ 0 & 0 & 0 & 0 & 0\end{matrix}\right) \qquad \text{(13)}$$

### Cooperation Relationship of the Protection Devices

For the widely used two-stage protection, there are four cooperation relationships between the main protection and the backup protection in the line. The improved protection action matrix can conveniently express these cooperation relationships as follows:

$$\text{Γ} \tilde{\text{N}} \text{+} \text{ΓΔ=} {\text{Θ}}_{\text{I}} \qquad \text{(14)}$$

$$\text{Γ} \tilde{\text{N}} \text{+} \text{ΛΔ=} {\text{Θ}}_{\text{II}} \qquad \text{(15)}$$

$$\text{Λ} \tilde{\text{N}} \text{+} \text{ΛΔ=} {\text{Θ}}_{\text{III}} \qquad \text{(16)}$$

$$\text{Λ} \tilde{\text{N}} \text{+} \text{ΓΔ=} {\text{Θ}}_{\text{IV}} \qquad \text{(17)}$$

Relationship 1: As shown in the formula (14), Θ_{I} represents that the main protection on two sides of the faulty line cooperates with each other to remove the fault.

Relationship 2: As shown in the formula (15), Θ_{II} represents that the backup protection on the two sides of the faulty line cooperates with each other to remove the fault.

Relationship ¾: As shown in the formulas (16) and (17), Θ_{III} and Θ_{IV} represent that the main protection on one side of the faulty line cooperates with the backup protection on the other side of the faulty line to remove the fault.

### Fault Clearing Time in the Action Matrix is Corrected

The fault clearing time used in the formulas (9) to (17) is a specified value obtained from a power company. Theoretically, the fault clearing time of the main protection or the backup protection on the two sides of the line should be the same and equal to the specified value. However, in actual operation, due to error, the elements in these matrices may deviate from specified values, so necessary corrections need to be made, as shown in formula (18):

$$\left\{\begin{matrix}{γ}_{i j} = {γ}_{i j , s e t} + {δ}_{1 , i j} \\ {λ}_{i j} = {λ}_{i j , s e t} + {δ}_{2 , i j}\end{matrix}\right) ; i , j ∈ \left[1 , n\right] ; i \neq j \qquad \text{(18)}$$

In the above formula, ^{γ}ᵢⱼ,ₛₑₜ and ^{λ}ᵢⱼ,ₛₑₜ respectively represent specified values of the main protection and the backup protection. ^{δ}_{1,ij} and ^{δ}₂,ᵢⱼ respectively represent deviations between actual fault clearing time and the specified values. The deviations are random numbers within [0, δ ], where δ represents a maximum error value during the testing or historical operation of relay protection devices of the same model.

3. The faulty line set is obtained by solving equations.

One or more possible faulty lines can be obtained by solving based on the sag cause identification in step 1 and the content of the protection action matrix in step 2 to reduce the calculation amount of the state estimation of the multi-stage voltage sag.

### Sag Type

The following four voltage sag types are defined based on the sag cause identification in step 1:
Type 1: single-stage rectangular sag,
Type 2: multi-stage voltage sag due to the cause 1,
Type 3: multi-stage voltage sag due to the cause 2, and
Type 4: multi-stage voltage sag due to the cause 1 and the cause 2.

### The Faulty Line Set is Obtained for Different Types of Sags by Solving Equations

Type 1 and 2: In these two types of voltage sag events, the relay protection devices on the two sides of the faulty line act simultaneously at a time point of the last sudden voltage sag change to remove the fault. Assuming that time points at which first and last sudden voltage sag change points of the waveform of the voltage sag are detected in step 1 are t₀ and tₛ respectively, the time length from the occurrence of the fault to removal of the fault in the system is tₛ-t₀ . If two elements of symmetric positions of the main diagonal line of a matrix in formulas (14) to (17) are equal to tₛ-t₀ within an error threshold, lines corresponding to these two elements are possible faulty lines. Therefore, a solution model of the faulty line set LF is as follows:

$$\left\{\begin{matrix}L F = \left\{\text{L} , {l}_{i j} , \text{L}\right\} \\ \text{s} \text{.t} \text{.} L F ⊆ L N \\ \sqrt{\left|{θ}_{i j} - \left({t}_{s} - {t}_{0}\right)\right| + \left|{θ}_{j i} - \left({t}_{s} - {t}_{0}\right)\right|} \leq \\ \sqrt{max \left({δ}_{1 , i j} , {δ}_{1 , j i}\right) + max \left({δ}_{2 , i j} , {δ}_{2 , j i}\right)} \leq \sqrt{2 δ} \\ i , j ∈ \left[1 , n\right] ; i \neq j\end{matrix}\right) \qquad \text{(19)}$$

Where ^{θ}ᵢⱼ represents an element in an i ^{th} row and a j ^{th} column in the matrices Θ_{I} to Θ_{IV} and LN represents a set of lines in the intersection of sag domains of a bus of a monitoring device.

Type 3 and 4: In these two types of voltage sag events, the relay protection devices on the two sides of the faulty line cannot act simultaneously to remove the fault. It is assumed that the time point at which the first sudden voltage sag change point of the waveform of the voltage sag is detected in step 1 and time points of sudden voltage sag change points of two corresponding relay protection actions are t₀, tₓ₋₁, and tₛ respectively. The time length from the occurrence of the fault to the protection actions of the relay protection devices on the two sides of the faulty line are tₓ₋₁-t₀ and tₛ -t₀, respectively. In this case, the solution model of the faulty line set is as follows:

$$\left\{\begin{matrix}L F = \left\{\text{L} , {l}_{i j} , \text{L}\right\} \\ \text{s} \text{.t} \text{.} L F ⊆ L N \\ \sqrt{\left|{θ}_{i j} - \left({t}_{s} - {t}_{0}\right)\right| + \left|{θ}_{j i} - \left({t}_{s} - {t}_{0}\right)\right|} \leq \\ \sqrt{max \left({δ}_{1 , i j} , {δ}_{1 , j i}\right) + max \left({δ}_{2 , i j} , {δ}_{2 , j i}\right)} \leq \sqrt{2 δ} \\ i , j ∈ \left[1 , n\right] ; i \neq j\end{matrix}\right) \qquad \text{(20)}$$

4. The impedance matrix is obtained by solving equations.

Whether caused by cause 1 or cause 2, the multi-stage voltage sag is essentially a change of a system impedance matrix due to an event during the fault.

### System Impedance Matrix Before the Fault

System admittance matrix Y^{SE} may be expressed as the sum of line admittance matrix

$${Y}_{L}^{S E}$$

and generator admittance matrix

$${Y}_{G}^{S E}$$

, as shown below:

$${Y}^{S E} = {Y}_{G}^{S E} + {Y}_{L}^{S E} \qquad \text{(21)}$$

Assuming there are ⁿ buses in the power system, the line admittance matrix

$${Y}_{L}^{S E}$$

can be calculated as follows based on a line topology relationship and an impedance parameter:

$${Y}_{L}^{S E} = \left(\begin{matrix}{α}_{11}^{s e} & {α}_{12}^{s e} & \text{L} & {α}_{1 n}^{s e} \\ {α}_{21}^{s e} & {α}_{22}^{s e} & \text{L} & {α}_{2 n}^{s e} \\ \text{M} & \text{M} & \text{O} & \text{M} \\ {α}_{n 1}^{s e} & {α}_{n 2}^{s e} & \text{L} & {α}_{n n}^{s e}\end{matrix}\right) \qquad \text{(22)}$$

In the above formula, se=1,2,0 represents a positive sequence, a negative sequence, and a zero sequence, α ᵢⱼ (i ≠ j; i, j ∈ [1,n]) represents mutual admittance of nodes i and j, and αᵢᵢ (i ∈ [1, n]) represents self-admittance of the node i.

The matrix

$${Y}_{G}^{S E}$$

is a diagonal matrix, and an element value on a diagonal line is equal to self-admittance of a corresponding generator, as shown below:

$${Y}_{G}^{S E} = \left(\begin{matrix}{β}_{11}^{s e} & 0 & \text{L} & 0 \\ 0 & {β}_{22}^{s e} & \text{L} & 0 \\ \text{M} & \text{M} & \text{O} & \text{M} \\ 0 & 0 & \text{L} & {β}_{n n}^{s e}\end{matrix}\right) \qquad \text{(23)}$$

where βᵢᵢ = 0(i ∈ [1, n]) represents that there is no generator for the bus.

The system impedance matrix can be calculated as follows according to the formula (21):

$${Z}_{N}^{S E} = {\left({Y}_{G}^{S E}\right)}^{- 1} = \left(\begin{matrix}{Z}_{11}^{s e} & {Z}_{12}^{s e} & \text{L} & {Z}_{1 n}^{s e} \\ {Z}_{21}^{s e} & {Z}_{22}^{s e} & \text{L} & {Z}_{2 n}^{s e} \\ \text{M} & \text{M} & \text{O} & \text{M} \\ {Z}_{n 1}^{s e} & {Z}_{n 2}^{s e} & \text{L} & {Z}_{n n}^{s e}\end{matrix}\right) \qquad \text{(24)}$$

### System Impedance Matrix After the Short Circuit Fault

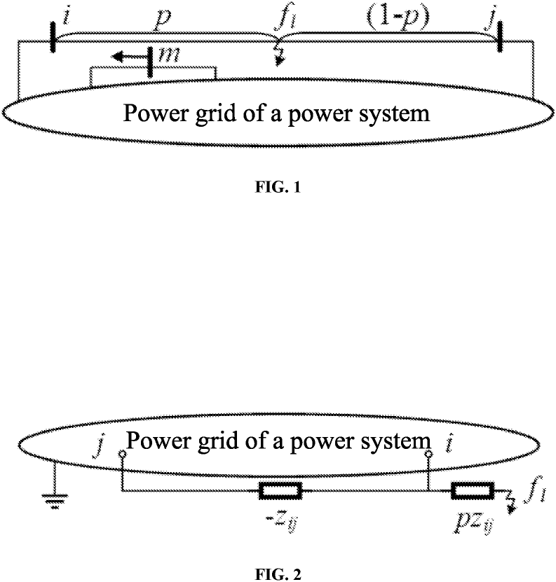

When the short circuit fault occurs in the system, system impedance can be calculated using a short-circuit calculation model of a complex power system shown in FIG. 1. Mutual impedance

$${Z}_{m f}^{s e}$$

between fault position fₗ and to-be-solved node ^{m} after the circuit short fault and self-impedance

$${Z}_{f f}^{s e}$$

of the fault position fₗ can be respectively obtained by solving the following two formulas:

$${Z}_{m f}^{s e} = \left(1 - p\right) {Z}_{m i}^{s e} + p {Z}_{m j}^{s e} = {g}_{m f 1} \left(i , j , p\right) \qquad \text{(25)}$$

$${Z}_{f f}^{s e} = \left\{\begin{matrix}{\left(1 - p\right)}^{2} {Z}_{i i}^{s e} + {p}^{2} {Z}_{j j}^{s e} + \\ 2 p \left(1 - p\right) {Z}_{i j}^{s e} + p \left(1 - p\right) {z}_{i j}^{s e}\end{matrix}\right\} = {g}_{f f 1} \left(i , j , p\right) \qquad \text{(26)}$$

Where

$${Z}_{m i}^{s e} , {Z}_{m j}^{s e} , {Z}_{i j}^{s e} , {Z}_{i i}^{s e} , \text{and} {Z}_{j j}^{s e}$$

are elements in the matrix

$${Z}_{N}^{S E} ; \text{and} {z}_{i j}^{s e}$$

represents impedance of the line ^{l}ᵢⱼ, where the impedance is further expressed as functions g_{mf1} (i, j,p) and g _{ff1} (i, j,p), and the two functions respectively represent mutual impedance between the fault position and the target node ^{m} and self-impedance of the fault position when the short circuit fault occurs at the position ^{f}ₗ far from terminal P of the node i on the line ^{l}ᵢⱼ .

### Impedance Matrix in the Case of a Relay Protection Action on One Side of the Faulty Line

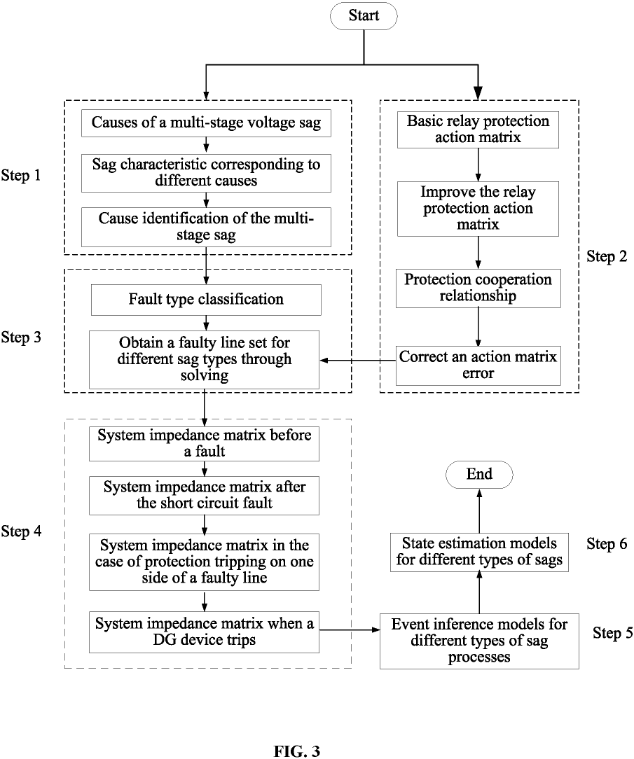

Assuming that after the short circuit fault occurs on the line lᵢⱼ, a j -side protection device acts to cut off the line on the corresponding side, and the system impedance can be calculated by using the model shown in FIG. 2.

First, a branch with impedance of -zᵢⱼ is added between the i -side bus and the j -side bus in the original system. In this case, the system impedance matrix

$${Z}_{A T}^{S E}$$

can be corrected according to the following formula:

$$\begin{matrix}{Z}_{A T}^{S E} = {Z}_{N}^{S E} - \frac{\text{Δ} Z \text{Δ} {Z}^{T}}{- {z}_{i j}^{s e} + {Z}_{i i}^{s e} + {Z}_{j j}^{s e} - 2 {Z}_{i j}^{s e}} \\ = \left(\begin{matrix}{Z}_{11 , \text{AT}}^{s e} & {Z}_{12 , \text{AT}}^{s e} & \text{L} & {Z}_{1 n , \text{AT}}^{s e} \\ {Z}_{21 , \text{AT}}^{s e} & {Z}_{22 , \text{AT}}^{s e} & \text{L} & {Z}_{2 n , \text{AT}}^{s e} \\ \text{M} & \text{M} & \text{O} & \text{M} \\ {Z}_{n 1 , \text{AT}}^{s e} & {Z}_{n 2 , \text{AT}}^{s e} & \text{L} & {Z}_{n n , \text{AT}}^{s e}\end{matrix}\right)\end{matrix} \qquad \text{(27)}$$

Where ΔZ can be calculated according to the following formula:

$$\text{Δ} Z = {\left[\begin{matrix}{Z}_{1 j}^{s e} - {Z}_{1 i}^{s e} & {Z}_{2 j}^{s e} - {Z}_{2 i}^{s e} & ⋯ & {Z}_{n j}^{s e} - {Z}_{n i}^{s e}\end{matrix}\right]}^{T} \qquad \text{(28)}$$

Then, a branch with impedance of ^{pz}ᵢⱼ is added to the i -side bus. In this case, the system impedance matrix is further corrected as

$${Z}_{A R P}^{S E}$$

according to the following formula:

$${Z}_{A R P}^{S E} = \left(\begin{matrix}{Z}_{11 , A T}^{s e} & {Z}_{12 , A T}^{s e} & \text{L} & {Z}_{1 n , A T}^{s e} & {Z}_{1 i , A T}^{s e} \\ {Z}_{21 , A T}^{s e} & {Z}_{22 , A T}^{s e} & \text{L} & {Z}_{2 n , A T}^{s e} & {Z}_{2 i , A T}^{s e} \\ \text{M} & \text{M} & \text{O} & \text{M} & \text{M} \\ {Z}_{n 1 , A T}^{s e} & {Z}_{n 2 , A T}^{s e} & \text{L} & {Z}_{n n , A T}^{s e} & {Z}_{n i , A T}^{s e} \\ {Z}_{i 1 , A T}^{s e} & {Z}_{i 2 , A T}^{s e} & \text{L} & {Z}_{i n , A T}^{s e} & {Z}_{i i , A T}^{s e} + p {z}_{i j}\end{matrix}\right) \qquad \text{(29)}$$

Compared with the

$${Z}_{A T}^{S E} , {Z}_{A R P}^{S E}$$

adds one line and one column to represent the mutual impedance

$${Z}_{m f}^{s e}$$

between the fault position f and each target bus ^{m} or the self-impedance

$${Z}_{f f}^{s e}$$

of the fault position. The impedance is further expressed as functions g _{mf 2} (i, j, p, d) and g_{ff 2} (i, j, p, d), where the two functions respectively represent mutual impedance between the fault position and the target node ^{m} and self-impedance of the fault position when a d -side protection device on the line acts to cut off a part of the line after the short circuit fault occurs at the position f far from the terminal P of the node i on the line lᵢⱼ, as shown in the following formulas:

$${Z}_{m f}^{s e} = {Z}_{i m , \text{AT}}^{s e} = {g}_{m f 2} \left(i , j , p , d\right) ; d = i \text{or} j \qquad \text{(30)}$$

and

$${Z}_{f f}^{s e} = {Z}_{i i , \text{AT}}^{s e} + p {z}_{i j} = {g}_{f f 2} \left(i , j , p , d\right) ; d = i \text{or} j \qquad \text{(31)}$$

### Impedance Matrix When the DG Device is Disconnected From the Power Grid

When the short circuit fault occurs, DG devices on some nodes may be disconnected from the power grid due to insufficient low-voltage ride through capabilities. Assuming that DG devices of all buses in bus set h are disconnected from the power grid, the matrix shown in the formula (23) first needs to be corrected as follows:

$${Y}_{G}^{S E} = \left(\begin{matrix}{β}_{11}^{s e} & 0 & \text{L} & 0 \\ 0 & {β}_{22}^{s e} & \text{L} & 0 \\ \text{M} & \text{M} & \text{O} & \text{M} \\ 0 & 0 & \text{L} & {β}_{n n}^{s e}\end{matrix}\right) ; {β}_{i i}^{s e} = 0 ; ∀ i ∈ h \qquad \text{(32)}$$

Then, the system impedance matrix before the fault is calculated by substituting the above formula into the formula (24). Finally, system impedance when the DG device is disconnected from the power grid in the case of the short circuit fault is calculated according to the formulas (1) to (26). The impedance is further expressed as functions g _{mf 3} (i, j, p, h) and g _{ff}₃ (i, j, p,h), where the two functions respectively represent mutual impedance between the fault position and the target node ^{m} and self-impedance of the fault position after the short circuit fault occurs at the position f far from the terminal P of the node i on the line lᵢⱼ, and the DG devices of all the buses in the bus set h are disconnected from the power grid, as shown in the following formulas:

$${Z}_{m f}^{s e} = {g}_{m f 3} \left(i , j , p , h\right) \qquad \text{(33)}$$

and

$${Z}_{f f}^{s e} = {g}_{f f 3} \left(i , j , p , h\right) \qquad \text{(34)}$$

5. The specific event at each stage of the multi-stage voltage sag is inferred.

After the system impedance matrices under different situations are obtained by solving equations in step 4, an optimization model in step 5 may be used to infer a specific faulty line from the faulty line set obtained in step 3, and the specific event of each stage of the multi-stage voltage sag is inferred. There are also the following four inference models based on the sag types:

### Type 1

For this type of sag, the following optimization model may be used to infer the faulty line and its short circuit condition (in other words, i, j, and p ):

$$\left\{\begin{matrix}max \text{-} \sqrt{\left|f \left({g}_{m f 1} \left(i , j , p\right) , {g}_{f f 1} \left(i , j , p\right)\right)\right| - {u}_{1}} \\ \text{s} \text{.t} \text{.} i , j ∈ \left[1 , n\right] ; i \neq j\end{matrix}\right) \qquad \text{(35)}$$

Where f ( ) represents a short-circuit calculation function, and calculation formulas of different types of short circuit faults are shown in the formulas (2) to (6).

### Type 2

For this type of sag, the following optimization model may be used to infer the faulty line and its short circuit condition, and a time point and a sequence of disconnecting the DG device from the power grid (in other words, i, j, p, and h_{q})_{:}

$$\left\{\begin{matrix}max \text{-} \left(\begin{matrix}\sqrt{\left|f \left({g}_{m f 1} \left(i , j , p\right) , {g}_{f f 1} \left(i , j , p\right)\right)\right| - {u}_{1}} + \\ {\sum }_{x = 2}^{s} {\sum }_{q = 1}^{s - 1} \sqrt{\left|f \left({g}_{m f 3} \left(i , j , p , {h}_{q}\right) , {g}_{f f 3} \left(i , j , p , {h}_{q}\right)\right)\right| - {u}_{x}}\end{matrix}\right) \\ \text{s} \text{.t} \text{.} i , j ∈ \left[1 , n\right] ; i \neq j ; {h}_{1} ⊆ {h}_{2} ⊆ ⋯ ⊆ {h}_{s - 1}\end{matrix}\right) \qquad \text{(36)}$$

### Type 3

For this type of sag, the following optimization model may be used to infer the faulty line and its short circuit condition, and a tripping time point and sequence of the relay protection device (in other words, i, j, p, and d ):

$$\left\{\begin{matrix}max \text{-} \left(\begin{matrix}\sqrt{\left|f \left({g}_{m f 1} \left(i , j , p\right) , {g}_{f f 1} \left(i , j , p\right)\right)\right| - {u}_{1}} + \\ \sqrt{\left|f \left({g}_{m f 2} \left(i , j , p , d\right) , {g}_{f f 2} \left(i , j , p , d\right)\right)\right| - {u}_{2}}\end{matrix}\right) \\ \text{s} \text{.t} \text{.} i , j ∈ \left[1 , n\right] ; i \neq j\end{matrix}\right) \qquad \text{(37)}$$

### Type 4

It is assumed that an o ^{th} sudden voltage sag change point detected in a waveform segment of the voltage sag corresponds to a single-side protection trip. For this type of sag, the following optimization model may be used to infer the faulty line and its short circuit condition, the tripping time point and sequence of the relay protection device, and the time point and the sequence of the DG device disconnected from the power grid (in other words, i, j, p, d, and ^{h}q ):

$$\left\{\begin{matrix}max \text{-} \left(\begin{matrix}\sqrt{\left|f \left({g}_{m f 1} \left(i , j , p\right) , {g}_{f f 1} \left(i , j , p\right)\right)\right| - {u}_{1}} + \\ {\sum }_{x = 2}^{o} {\sum }_{q = 1}^{o - 1} \sqrt{\left|f \left({g}_{m f 3} \left(i , j , p , {h}_{q}\right) , {g}_{f f 3} \left(i , j , p , {h}_{q}\right)\right)\right| - {u}_{x}} \\ + \left|f \left({g}_{m f 2} \left(i , j , p , d\right) , {g}_{f f 2} \left(i , j , p , d\right)\right)\right| - {u}_{o + 1} + \\ {\sum }_{x = o + 2}^{s} {\sum }_{h = 0}^{s - 2} \sqrt{\left|f \left({g}_{m f 3} \left(i , j , p , {h}_{q}\right) , {g}_{f f 3} \left(i , j , p , {h}_{q}\right)\right)\right| - {u}_{x}}\end{matrix}\right) \\ \text{s} \text{.t} \text{.} i , j ∈ \left[1 , n\right] ; i \neq j ; {h}_{1} ⊆ {h}_{2} ⊆ ⋯ ⊆ {h}_{s - 2}\end{matrix}\right) \qquad \text{(38)}$$

It should be noted that the formulas (35) to (38) are optimization models for a single monitoring device, which can be obtained through solving by using an intelligent algorithm such as a quantum genetic algorithm. When there are a plurality of monitoring devices, an objective function in the optimization model is the sum of respective objectives functions of the monitoring devices.

6. The state estimation method for the multi-stage voltage sag is inferred.

In voltage sag state estimation, a sag amplitude and duration of an unmonitored bus must be estimated. Duration of each sag stage can be estimated based on the time length between adjacent sudden voltage sag change points. The sag amplitude is estimated based on an event inference result in step 5. Similarly, there may be the following four voltage sag state estimation methods based on the voltage sag types:

### Type 1

For this type of sag, a sag amplitude of any unmonitored bus ^{m} may be estimated according to the following formula:

$$f \left({g}_{m f 1} \left(i , j , p\right) , {g}_{f f 1} \left(i , j , p\right)\right) \qquad \text{(39)}$$

### Type 2

For this type of sag, a sag amplitude of any unmonitored bus ^{m} may be estimated according to the following formula:

$$\left\{\begin{matrix}{u}_{1} = f \left({g}_{m f 1} \left(i , j , p\right) , {g}_{f f 1} \left(i , j , p\right)\right) \\ {u}_{x} = f \left({g}_{m f 3} \left(i , j , p , {h}_{x - 1}\right) , {g}_{f f 3} \left(i , j , p , {h}_{x - 1}\right)\right)\end{matrix}\right) \qquad \text{(40)}$$

### Type 3

For this type of sag, a sag amplitude of any unmonitored bus ^{m} may be estimated according to the following formula:

$$\left\{\begin{matrix}{u}_{1} = f \left({g}_{m f 1} \left(i , j , p\right) , {g}_{f f 1} \left(i , j , p\right)\right) \\ {u}_{2} = f \left({g}_{m f 2} \left(i , j , p , d\right) , {g}_{f f 2} \left(i , j , p , d\right)\right)\end{matrix}\right) \qquad \text{(41)}$$

### Type 4

For this type of sag, a sag amplitude of any unmonitored bus ^{m} may be estimated according to the following formula:

$$\left\{\begin{matrix}{u}_{1} = f \left({g}_{m f 1} \left(i , j , p\right) , {g}_{f f 1} \left(i , j , p\right)\right) \\ {u}_{x} = f \left({g}_{m f 3} \left(i , j , p , {h}_{x - 1}\right) , {g}_{f f 3} \left(i , j , p , {h}_{x - 1}\right)\right) \\ {u}_{y} = f \left({g}_{m f 2} \left(i , j , p , d\right) , {g}_{f f 2} \left(i , j , p , d\right)\right) \\ {u}_{z} = f \left({g}_{m f 3} \left(i , j , p , {h}_{z - 1}\right) , {g}_{f f 3} \left(i , j , p , {h}_{z - 1}\right)\right) \\ x ∈ \left[2 , y - 1\right] ; z ∈ \left[y + 1 , s - 2\right]\end{matrix}\right) \qquad \text{(42)}$$

The method in the present disclosure analyzes characteristics of multi-stage voltage sags due to different causes, considers sudden change time of each stage and fault clearing time of a relay protection device in the monitoring data of the multi-stage voltage sag, infers a specific event that may occur in each stage of the multi-stage voltage sag, and finally obtains a multi-stage state estimation method that meets project requirements.

What is claimed is:

1. A state estimation method for a multi-stage voltage sag, comprising the following steps:
step 1: analyzing causes of a multi-stage voltage sag, determining characteristics of multi-stage voltage sags due to different causes, and identifying causes of voltage sags at different sudden change points accordingly;
step 2: building an action matrix of a relay protection device based on a specified fault clearing time at different positions of a power grid;
step 3: obtaining one or more possible faulty lines through solving to form a faulty line set to reduce a calculation amount of state estimation of the multi-stage voltage sag;
step 4: calculating system impedance matrices before and after a fault, an impedance matrix in the case of a relay protection action on one side of the faulty line, and an impedance matrix when a distributed generation (DG) device is disconnected from the power grid;
step 5: using an optimization model to infer a specific faulty line from the faulty line set obtained in step 3, and inferring a specific event of each stage of the multi-stage voltage sag based on a voltage sag type; and
step 6: estimating duration of each sag stage based on the voltage sag type and a time length between adjacent sudden voltage sag change points, and estimating a sag amplitude based on an event inference result in step 5.

2. The state estimation method for a multi-stage voltage sag according to claim 1, wherein the causes and corresponding characteristics of the multi-stage voltage sag are as follows:
cause I: during a short circuit fault, one or more DG devices in a power system trip, resulting in a loss of a power supply of the power grid; and a corresponding characteristic is that a voltage amplitude on a right side of a corresponding sudden voltage sag change point when the voltage sag occurs is smaller than that on a left side; and
cause II: during the short circuit fault, relay protection devices on two sides of the faulty line trip at different time, resulting in a change of a topology of the power grid; and a corresponding characteristic is that the voltage amplitude on the right side of the corresponding sudden voltage sag change point when the voltage sag occurs is greater than that on the left side.

3. The state estimation method for a multi-stage voltage sag according to claim 2, wherein the identifying causes of voltage sags at different sudden change points specifically comprises:
assuming that for a waveform segment containing the voltage sag, a total of s + 1 sudden voltage sag change points are detected by using a waveform point detection method, which are respectively expressed as ^{MP}₀,^{MP}₁,...,^{MP}ₓ,...,^{MP}ₛ and correspond to s + 1 sudden change time points t₀,t₁,...,tₓ,...,tₛ, wherein these sudden voltage sag change points divide a waveform of the voltage sag into ^{s} segments; and voltages of the different waveform segments are respectively expressed as u_{1,}u₂,...,uₓ,...,uₛ, and an ^{m th} voltage ^{u}ₘ is calculated as follows:
$${u}_{m} = {\sum }_{j = f f * \left({t}_{m - 1} + 1 / f\right)}^{j = f f * {t}_{m}} {x}_{j} / \left(\left({t}_{m} - {t}_{m - 1} + 1 / f\right) * f f\right) ; j ∈ \left[1 , k\right]$$
wherein ƒƒ represents a sampling rate in units of piece/second; ƒ represents a power-frequency current frequency in units of Hz; ^{x}ⱼ represents a j ^{th} value in an effective value sequence; m ∈ [1,s] ; and k represents a total quantity of sampling points; and
forming a binary vector W according to the above formula:
$$\left\{\begin{matrix}W = \left[{w}_{1} , {w}_{2} , \text{L} , {w}_{x} , \text{L} , {w}_{s}\right] , x ∈ \left[1 , s\right] \\ {w}_{x} = \left\{\begin{matrix}0 , \text{if} {u}_{x} < {u}_{x - 1} \text{or} x = 1 \\ 1 , \text{if} {u}_{x} < {u}_{x - 1}\end{matrix}\right)\end{matrix}\right)$$
wherein a value of the element ^{w}ₓ in the vector W is 0 or 1; when the value of the ^{w}ₓ is 0, it indicates that a voltage on a right side of ^{MP}ₓ₋₁ corresponding to a time point ^{t}ₓ₋₁ is less than that on a left side, which means that the multi-stage voltage sag is formed due to the cause I at this time point, wherein x > 1; on the contrary, when the value of the ^{w}ₓ is 1, it means that the multi-stage voltage sag is formed due to the cause II at the time point ^{t}ₓ₋₁, wherein x > 1.

4. The state estimation method for a multi-stage voltage sag according to claim 3, wherein the building an action matrix of a relay protection device in step 2 specifically comprises:
step 2.1: building a basic action matrix, in other words, a universal matrix describing a fault removal behavior of the relay protection device:
$$Γ = \left(\begin{matrix}0 & {γ}_{12} & {γ}_{13} & \text{L} & {γ}_{1 n} \\ {γ}_{21} & 0 & {γ}_{23} & \text{L} & {γ}_{2 n} \\ {γ}_{31} & {γ}_{32} & 0 & \text{O} & \text{M} \\ \text{M} & \text{M} & \text{O} & 0 & {γ}_{\left(n - 1\right) n} \\ {γ}_{n 1} & {γ}_{n 2} & \text{L} & {γ}_{n \left(n - 1\right)} & 0\end{matrix}\right)$$
wherein n represents a quantity of buses in the system, ^{γ}ᵢⱼ and ^{γ}ⱼᵢ respectively represent fault clearing time of protection devices close to i -side and j -side buses on a line ^{l}ᵢⱼ, i, j ∈ [1, n];i ≠ j, and ^{γ}ᵢⱼ,^{γ}ⱼᵢ = 0 represents that there is no physical connection between the i -side bus and the j -side bus;
step 2.2: improving the universal matrix and decoupling an improved universal matrix into two matrices:
$$Γ \tilde{Ν} = \left(\begin{matrix}0 & 0 & 0 & 0 & 0 \\ {γ}_{21} & 0 & 0 & 0 & 0 \\ {γ}_{31} & {γ}_{32} & 0 & 0 & 0 \\ \text{M} & \text{M} & \text{O} & 0 & 0 \\ {γ}_{n 1} & {γ}_{n 2} & \text{L} & {γ}_{n \left(n - 1\right)} & 0\end{matrix}\right)$$
$$Γ Δ = \left(\begin{matrix}0 & {γ}_{12} & {γ}_{13} & \text{L} & {γ}_{1 n} \\ 0 & 0 & {γ}_{23} & \text{L} & {γ}_{2 n} \\ 0 & 0 & 0 & \text{O} & \text{M} \\ 0 & 0 & 0 & 0 & {γ}_{\left(n - 1\right) n} \\ 0 & 0 & 0 & 0 & 0\end{matrix}\right)$$
wherein the upper and lower triangular matrices respectively represent fault clearing time of protective devices of a same type on two terminal buses of the line; a lower triangular element in the lower triangular matrix represents the fault clearing time of the protection device of the i -side bus of the line ^{l}ᵢⱼ, and ^{γ}ᵢⱼ⁼⁰ and ⁱ^{>}^{j} represent that there is no physical connection between the i -side bus and the ^{j} -side bus; and an upper triangular element in the upper triangular matrix represents a parameter on the other side of the line; and
to represent two-stage protection, two other similar matrices are constructed to represent parameters of backup protection:
$$Λ \tilde{Ν} = \left(\begin{matrix}0 & 0 & 0 & 0 & 0 \\ {λ}_{21} & 0 & 0 & 0 & 0 \\ {λ}_{31} & {λ}_{32} & 0 & 0 & 0 \\ \text{M} & \text{M} & \text{O} & 0 & 0 \\ {λ}_{n 1} & {λ}_{n 2} & \text{L} & {λ}_{n \left(n - 1\right)} & 0\end{matrix}\right)$$
$$Λ Δ = \left(\begin{matrix}0 & {λ}_{12} & {λ}_{13} & \text{L} & {λ}_{1 n} \\ 0 & 0 & {λ}_{23} & \text{L} & {λ}_{2 n} \\ 0 & 0 & 0 & \text{O} & \text{M} \\ 0 & 0 & 0 & 0 & {λ}_{\left(n - 1\right) n} \\ 0 & 0 & 0 & 0 & 0\end{matrix}\right)$$
step 2.3: determining a cooperation relationship of the protection devices, wherein
for the two-stage protection, there are four cooperation relationships between main protection and the backup protection in the line, and the improved protection action matrix is expressed as the following cooperation relationships:
$$Γ \tilde{Ν} + Γ Δ = {Θ}_{\text{I}}$$
$$Γ \tilde{Ν} + Λ Δ = {Θ}_{\text{II}}$$
$$Λ \tilde{Ν} + Λ Δ = {Θ}_{\text{III}}$$
$$Λ \tilde{Ν} + Γ Δ = {Θ}_{\text{IV}}$$
wherein Θ_{I} represents that the main protection on the two sides of the faulty line cooperates with each other to remove the fault; Θ_{II} represents that the backup protection on the two sides of the faulty line cooperates with each other to remove the fault; Θ_{III} and Θ_{IV} represent that the main protection on one side of the faulty line cooperates with the backup protection on the other side of the faulty line to remove the fault; and
step 2.4: correcting fault clearing time in the action matrix, wherein
the fault clearing time is corrected as follows:
$$\left\{\begin{matrix}{γ}_{i j} = {γ}_{i j , s e t} + {δ}_{1 , i j} \\ {λ}_{i j} = {λ}_{i j , s e t} + {δ}_{2 , i j}\end{matrix}\right) ; i , j ∈ \left[1 , n\right] ; i \neq j$$
wherein ^{γ}ij,set and ^{η}ij,set respectively represent specified values of the main protection and the backup protection; ^{δ}_{1,ij} and ^{δ}₂,ᵢⱼ respectively represent deviations between actual fault clearing time and the specified values; and the deviations are random numbers within [0, ^{δ}], wherein δ represents a maximum error value during testing or historical operation of relay protection devices of a same model.

5. The state estimation method for a multi-stage voltage sag according to claim 4, wherein step 3 specifically comprises:
step 3.1: defining the following four voltage sag types based on the sag cause identification in step 1:
type I: single-stage rectangular sag;
type II: multi-stage voltage sag due to the cause I;
type III: multi-stage voltage sag due to the cause II; and
type IV: multi-stage voltage sag due to the cause I and the cause II; and
step 3.2: obtaining the faulty line set for different types of sags, wherein
for the type I and the type II:
assuming that time points at which first and last sudden voltage sag change points of the waveform of the voltage sag are detected in step 1 are ^{t}₀ and ^{t}ₛ respectively, a time length from occurrence of the fault to removal of the fault in the system is ^{t}ₛ-^{t}₀ ; and if two elements of symmetric positions of a main diagonal line of a matrix in the four matrices in step 2.3 are equal to tₛ-t₀ within an error threshold, lines corresponding to these two elements are possible faulty lines, and therefore, a solution model of the faulty line set LF is as follows:
$$\left\{\begin{matrix}L F = \left\{\text{L,} {l}_{i j} , \text{L}\right\} \\ \text{s} \text{.t} \text{.} L F ⊆ L N \\ \sqrt{\left|{θ}_{i j} - \left({t}_{s} - {t}_{0}\right)\right| + \left|{θ}_{j i} - \left({t}_{s} - {t}_{0}\right)\right|} \leq \\ \sqrt{max \left({δ}_{1 , i j} , {δ}_{1 , j i}\right) + max \left({δ}_{2 , i j} , {δ}_{2 , j i}\right)} \leq \sqrt{2 δ} \\ i , j ∈ \left[1 , n\right] ; i \neq j\end{matrix}\right)$$
wherein ^{θ}ᵢⱼ represents an element in an i ^{th} row and a j ^{th} column in the matrices
$${Θ}_{\text{I}}$$
to
$${Θ}_{\text{IV}} ,$$
and LN represents a set of lines in an intersection of sag domains of a bus of a monitoring device; and
for the type III and the type IV:
assuming that the time point at which the first sudden voltage sag change point of the waveform of the voltage sag detected in step 1 is t₀, and time points of sudden voltage sag change points of two corresponding relay protection actions are tₓ₋₁ and tₛ respectively, a time length from the occurrence of the fault to the protection actions of the relay protection devices on the two sides of the faulty line are tₓ₋₁-t₀ and tₛ-t₀ respectively; and in this case, the solution model of the faulty line set is as follows:
$${\left\{\begin{matrix}L F = \left\{\text{L,} {l}_{i j} , \text{L}\right\} \\ \text{s} \text{.t} \text{.} L F ⊆ L N \\ \sqrt{\left|{θ}_{i j} - \left({t}_{s} - {t}_{0}\right)\right| + \left|{θ}_{j i} - \left({t}_{s} - {t}_{0}\right)\right|} \leq \\ \sqrt{max \left({δ}_{1 , i j} , {δ}_{1 , j i}\right) + max \left({δ}_{2 , i j} , {δ}_{2 , j i}\right)} \leq \sqrt{2 δ} \\ i , j ∈ \left[1 , n\right] ; i \neq j ; s \geq 2 ; {w}_{x} = 1\end{matrix}\right)}_{.}$$
.

6. The state estimation method for a multi-stage voltage sag according to claim 5, wherein step 4 specifically comprises:
step 4.1: calculating the system impedance matrix before the fault, wherein
a system admittance matrix Y^{SE} is expressed as a sum of a line admittance matrix
$${Y}_{L}^{S E}$$
and a generator admittance matrix,
$${Y}_{G}^{S E}$$
as shown below:
$${Y}^{S E} = {Y}_{G}^{S E} + {Y}_{L}^{S E}$$
assuming there are ⁿ buses in the power system, the line admittance matrix
$${Y}_{L}^{S E}$$
is calculated as follows based on a line topology relationship and an impedance parameter:
$${Y}_{L}^{S E} = \left(\begin{matrix}{α}_{11}^{s e} & {α}_{12}^{s e} & \text{L} & {α}_{1 n}^{s e} \\ {α}_{21}^{s e} & {α}_{22}^{s e} & \text{L} & {α}_{2 n}^{s e} \\ \text{M} & \text{M} & \text{O} & \text{M} \\ {α}_{n 1}^{s e} & {α}_{n 2}^{s e} & \text{L} & {α}_{n m}^{s e}\end{matrix}\right)$$
wherein se = 1,2,0 represents a positive sequence, a negative sequence, and a zero sequence, ^{α}ᵢⱼ represents mutual admittance of nodes i and j, αᵢᵢ represents self-admittance of the node ⁱ, and i ≠ j; i, j ∈ [1,n];
the matrix
$${Y}_{G}^{S E}$$
is a diagonal matrix, and an element value on a diagonal line is equal to self-admittance of a corresponding generator, as shown below:
$${Y}_{G}^{S E} = \left(\begin{matrix}{β}_{11}^{s e} & 0 & \text{L} & 0 \\ 0 & {β}_{22}^{s e} & \text{L} & 0 \\ \text{M} & \text{M} & \text{O} & \text{M} \\ 0 & 0 & \text{L} & {β}_{n m}^{s e}\end{matrix}\right)$$
wherein ^{β}ᵢᵢ = 0 represents that there is no generator for the bus; and
the system impedance matrix is calculated as follows:
$${Z}_{N}^{S E} = {\left({Y}_{L}^{S E}\right)}^{- 1} = \left(\begin{matrix}{Z}_{11}^{s e} & {Z}_{12}^{s e} & \text{L} & {Z}_{1 n}^{s e} \\ {Z}_{21}^{s e} & {Z}_{22}^{s e} & \text{L} & {Z}_{2 n}^{s e} \\ \text{M} & \text{M} & \text{O} & \text{M} \\ {Z}_{n 1}^{s e} & {Z}_{n 2}^{s e} & \text{L} & {Z}_{n m}^{s e}\end{matrix}\right)$$
step 4.2: calculating the system impedance matrix after the short circuit fault, wherein
mutual impedance
$${Z}_{m f}^{s e}$$
between a fault position ƒ
ₗ and a to-be-solved node ^{m} after the circuit short fault, and self-impedance
$${Z}_{f f}^{s e}$$
of the fault position ƒ
ₗ are respectively obtained through solving according to the following two formulas:
$${Z}_{m f}^{s e} = \left(1 - p\right) {Z}_{m i}^{s e} + p {Z}_{m j}^{s e} = {g}_{m f 1} \left(i , j , p\right)$$
$${Z}_{f f}^{s e} = \left\{\begin{matrix}{\left(1 - p\right)}^{2} {Z}_{i i}^{s e} + {p}^{2} {Z}_{j j}^{s e} + \\ 2 p \left(1 - p\right) {Z}_{i j}^{s e} + p \left(1 - p\right) {z}_{i j}^{s e}\end{matrix}\right\} = {g}_{j j 1} \left(i , j , p\right)$$
wherein
$${Z}_{m i}^{s e}$$
,
$${Z}_{m j}^{s e}$$
,
$${Z}_{i j}^{s e}$$
,
$${Z}_{i i}^{s e}$$
, and
$${Z}_{j j}^{s e}$$
are elements in the matrix
$${Z}_{N}^{S E}$$
; and
$${z}_{i j}^{s e}$$
represents impedance of the line
^{l}ᵢⱼ, wherein the impedance is further expressed as functions g_{mf1}(i,j,p) and g_{ff1}(i,j,p), and the two functions respectively represent mutual impedance between the fault position and the target node ^{m} and self-impedance of the fault position when the short circuit fault occurs at the position ƒₗ having a distance P away from the i -side of the line lᵢⱼ;
step 4.3: calculating the impedance matrix in the case of the relay protection action on one side of the faulty line, wherein
assuming that after the short circuit fault occurs on the line ^{l}ᵢⱼ, a j -side protection device acts to cut off the line on the corresponding side, and the system impedance is calculated as follows:
first, a branch with impedance of ^{-z}ᵢⱼ is added between the i -side bus and the j -side bus in the original system, and in this case, the system impedance matrix
$${Z}_{A T}^{S E}$$
is corrected according to the following formula:
$$\begin{matrix}{Z}_{A T}^{S E} = {Z}_{N}^{S E} - \frac{\text{Δ} Z \text{Δ} {Z}^{T}}{- {z}_{i j}^{s e} + {Z}_{i i}^{s e} + {Z}_{j j}^{s e} - 2 {Z}_{i j}^{s e}} \\ = \left(\begin{matrix}{Z}_{11 , \text{AT}}^{s e} & {Z}_{12 , \text{AT}}^{s e} & \text{L} & {Z}_{1 n , \text{AT}}^{s e} \\ {Z}_{21 , \text{AT}}^{s e} & {Z}_{22 , \text{AT}}^{s e} & \text{L} & {Z}_{2 n , \text{AT}}^{s e} \\ \text{M} & \text{M} & \text{O} & \text{M} \\ {Z}_{n 1 , \text{AT}}^{s e} & {Z}_{n 2 , \text{AT}}^{s e} & \text{L} & {Z}_{n n , \text{AT}}^{s e}\end{matrix}\right)\end{matrix}$$
wherein ΔZ represents a process quantity, which is calculated according to the following formula:
$$\text{Δ} Z = {\left[\begin{matrix}{Z}_{1 j}^{s e} - {Z}_{1 i}^{s e} & {Z}_{2 j}^{s e} - {Z}_{2 i}^{s e} & \text{L} & {Z}_{n j}^{s e} - {Z}_{n i}^{s e}\end{matrix}\right]}^{\text{T}}$$
then a branch with impedance of ^{pz}ᵢⱼ is added to the i -side bus, and in this case, the system impedance matrix is further corrected as
$${Z}_{A R P}^{S E}$$
according to the following formula:
$${Z}_{A R P}^{S E} = \left(\begin{matrix}{Z}_{11 , A T}^{s e} & {Z}_{12 , A T}^{s e} & \text{L} & {Z}_{1 n , A T}^{s e} & {Z}_{1 i , A T}^{s e} \\ {Z}_{21 , A T}^{s e} & {Z}_{22 , A T}^{s e} & \text{L} & {Z}_{2 n , A T}^{s e} & {Z}_{2 i , A T}^{s e} \\ \text{M} & \text{M} & \text{O} & \text{M} & \text{M} \\ {Z}_{n 1 , A T}^{s e} & {Z}_{n 2 , A T}^{s e} & \text{L} & {Z}_{n n , A T}^{s e} & {Z}_{n i , A T}^{s e} \\ {Z}_{i 1 , A T}^{s e} & {Z}_{i 2 , A T}^{s e} & \text{L} & {Z}_{i n , A T}^{s e} & {Z}_{i i , A T}^{s e} + p {z}_{i j}\end{matrix}\right)$$
compared with the
$${Z}_{A T}^{S E}$$
, the
$${Z}_{A R P}^{S E}$$
adds one line and one column to represent the mutual impedance
$${Z}_{m f}^{s e}$$
between the fault position ƒ
ₗ and each target bus ^{m} or the self-impedance
$${Z}_{f f}^{s e}$$
of the fault position; and the impedance is further expressed as functions g
_{mf 2} (i,j,p,d) and g _{ff 2} (i, j, p, d), wherein the two functions respectively represent mutual impedance between the fault position and the target node ^{m} and self-impedance of the fault position when a d -side protection device on the line acts to cut off a part of the line after the short circuit fault occurs at the position ƒₗ far from the terminal P of the node i on the line ^{l}ᵢⱼ, as shown in the following formulas:
$${Z}_{m f}^{s e} = {Z}_{i m , \text{AT}}^{s e} = {g}_{m f 2} \left(i , j , p , d\right) ; d = i \text{or} j$$
$${Z}_{f f}^{s e} = {Z}_{i i , \text{AT}}^{s e} + p {z}_{i j} = {g}_{f f 2} \left(i , j , p , d\right) ; d = i \text{or} j$$
step 4.4: calculating the impedance matrix when the DG device is disconnected from the power grid, wherein
assuming that DG devices of all buses in a bus set h are disconnected from the power grid, the diagonal matrix first needs to be corrected as follows:
$${Y}_{G}^{S E} = \left(\begin{matrix}{β}_{11}^{s e} & 0 & \text{L} & 0 \\ 0 & {β}_{22}^{s e} & \text{L} & 0 \\ \text{M} & \text{M} & \text{O} & \text{M} \\ 0 & 0 & \text{L} & {β}_{n n}^{s e}\end{matrix}\right) ; {β}_{i i}^{s e} = 0 ; ∀ i ∈ h$$
the system impedance matrix before the fault is calculated according to the above formula, and finally system impedance when the DG device is disconnected from the power grid in the case of the short circuit fault is calculated; and the impedance is further expressed as functions g_{mf3} (i, j, p, h) and g_{ff3} (i, j, p, h), wherein the two functions respectively represent mutual impedance between the fault position and the target node ^{m} and self-impedance of the fault position after the short circuit fault occurs at the position ƒₗ far from the terminal P of the node i on the line lᵢⱼ and the DG devices of all the buses in the bus set h are disconnected from the power grid, as shown in the following two formulas:
$${Z}_{m f}^{s e} = {g}_{m f 3} \left(i , j , p , h\right)$$
$${Z}_{f f}^{s e} = {g}_{f f 3} \left(i , j , p , h\right) .$$
.

7. The state estimation method for a multi-stage voltage sag according to claim 6, wherein in step 5, the following four optimization models are available based on the sag types:
(1) for the type I, the following optimization model is used to infer the faulty line and its short circuit condition, in other words, i, j, and P ;
$$\left\{\begin{matrix}max \text{-} \sqrt{\left|f \left({g}_{m f 1} \left(i , j , p\right) , {g}_{f f 1} \left(i , j , p\right)\right)\right| - {u}_{1}} \\ \text{s} \text{.t} \text{.} i , j ∈ \left[1 , n\right] ; i \neq j\end{matrix}\right) ,$$
wherein ƒ (·) represents a short-circuit calculation function;
(2) for the type II, the following optimization model is used to infer the faulty line and its short circuit condition, a time point and a sequence of disconnecting the DG device from the power grid, in other words, i, j, p, and ^{h}_{q} ;
$$\left\{\begin{matrix}max \text{-} \left(\begin{matrix}\sqrt{\left|f \left({g}_{m f 1} \left(i , j , p\right) , {g}_{f f 1} \left(i , j , p\right)\right)\right| - {u}_{1}} + \\ {\sum }_{x = 2}^{s} {\sum }_{q = 1}^{s - 1} \sqrt{\left|f \left({g}_{m f 3} \left(i , j , p , {h}_{q}\right) , {g}_{f f 3} \left(i , j , p , {h}_{q}\right)\right)\right| - {u}_{x}}\end{matrix}\right) \\ \text{s} \text{.t} \text{.} i , j ∈ \left[1 , n\right] ; i \neq j ; {h}_{1} ⊆ {h}_{2} ⊆ ⋯ ⊆ {h}_{s \text{-1}}\end{matrix}\right)$$
wherein
^{s} represents a quantity of stages of the multi-stage voltage sag; and ^{h}_{q} represents a set of DG devices disconnected from the power grid during a q-stage voltage sag;
(3) for the type III, the following optimization model is used to infer the faulty line and its short circuit condition, and a tripping time point and sequence of the relay protection device, in other words, i, j, P, and d ;
$$\left\{\begin{matrix}max \text{-} \left(\begin{matrix}\sqrt{\left|f \left({g}_{m f 1} \left(i , j , p\right) , {g}_{f f 1} \left(i , j , p\right)\right)\right| - {u}_{1}} + \\ \sqrt{\left|f \left({g}_{m f 2} \left(i , j , p , d\right) , {g}_{f f 2} \left(i , j , p , d\right)\right)\right| - {u}_{2}}\end{matrix}\right) \\ \text{s} \text{.t} \text{.} i , j ∈ \left[1 , n\right] ; i \neq j\end{matrix}\right)$$
(4) for the type IV, the following optimization model is used to infer the faulty line and its short circuit condition, the tripping time point and sequence of the relay protection device, and the time point and the sequence of disconnecting the DG device from the power grid, in other words, i, j, p, d, and ^{h}_{q};
$$\left\{\begin{matrix}max \text{-} \left(\begin{matrix}\begin{matrix}\sqrt{\left|f \left({g}_{m f 1} \left(i , j , p\right) , {g}_{f f 1} \left(i , j , p\right)\right)\right| - {u}_{1}} + \\ {\sum }_{x = 2}^{o} {\sum }_{q = 1}^{o - 1} \sqrt{\left|f \left({g}_{m f 3} \left(i , j , p , {h}_{q}\right) , {g}_{f f 3} \left(i , j , p , {h}_{q}\right)\right)\right| - {u}_{x}}\end{matrix} \\ \begin{matrix}+ \left|f \left({g}_{m f 2} \left(i , j , p , d\right) , {g}_{f f 2} \left(i , j , p , d\right)\right)\right| - {u}_{o + 1} + \\ {\sum }_{x = o + 2}^{s} {\sum }_{q = o}^{s - 2} \sqrt{\left|f \left({g}_{m f 3} \left(i , j , p , {h}_{q}\right) , {g}_{f f 3} \left(i , j , p , {h}_{q}\right)\right)\right| - {u}_{x}}\end{matrix}\end{matrix}\right) \\ \text{s} \text{.t} \text{.} i , j ∈ \left[1 , n\right] ; i \neq j ; {h}_{1} ⊆ {h}_{2} ⊆ \text{L} ⊆ {h}_{s \text{-2}}\end{matrix}\right)$$
wherein ^{o} represents a time point at which a relay protection device on a side of the faulty line first acts to trip; and ^{u}ₒ₊₁ represents an amplitude of an o+1-stage voltage sag.

8. The state estimation method for a multi-stage voltage sag according to claim 7, wherein in step 6, the following four voltage sag state estimation methods are available based on the sag types:
1) for the type I, a sag amplitude of any unmonitored bus ^{m} is estimated according to the following formula:
$$f \left({g}_{m f 1} \left(i , j , p\right) , {g}_{f f 1} \left(i , j , p\right)\right)$$
2) for the type II, a sag amplitude of any unmonitored bus ^{m} is estimated according to the following formula:
$$\left\{\begin{matrix}{u}_{1} = f \left({g}_{m f 1} \left(i , j , p\right) , {g}_{f f 1} \left(i , j , p\right)\right) \\ {u}_{x} = f \left({g}_{m f 3} \left(i , j , p , {h}_{x - 1}\right) , {g}_{f f 3} \left(i , j , p , {h}_{x - 1}\right)\right)\end{matrix}\right)$$
3) for the type III, a sag amplitude of any unmonitored bus ^{m} is estimated according to the following formula:
$$\left\{\begin{matrix}{u}_{1} = f \left({g}_{m f 1} \left(i , j , p\right) , {g}_{f f 1} \left(i , j , p\right)\right) \\ {u}_{2} = f \left({g}_{m f 2} \left(i , j , p , d\right) , {g}_{f f 2} \left(i , j , p , d\right)\right)\end{matrix}\right)$$
4) for the type IV, a sag amplitude of any unmonitored bus ^{m} is estimated according to the following formula:
$$\left\{\begin{matrix}{u}_{1} = f \left({g}_{m f 1} \left(i , j , p\right) , {g}_{f f 1} \left(i , j , p\right)\right) \\ {u}_{x} = f \left({g}_{m f 3} \left(i , j , p , {h}_{x - 1}\right) , {g}_{f f 3} \left(i , j , p , {h}_{x - 1}\right)\right) \\ {u}_{y} = f \left({g}_{m f 2} \left(i , j , p , d\right) , {g}_{f f 2} \left(i , j , p , d\right)\right) \\ {u}_{z} = f \left({g}_{m f 3} \left(i , j , p , {h}_{z - 1}\right) , {g}_{f f 3} \left(i , j , p , {h}_{z - 1}\right)\right) \\ x ∈ \left[2 , y - 1\right] ; z ∈ \left[y + 1 , s - 2\right]\end{matrix}\right)$$
wherein ^{y} and z respectively represent y^{th} and z^{th} stages of the multi-stage voltage sag.
